(19) United States
(12) Patent Application Publication
(10) Pub. No.: US 2022/0326096 A1
(43) Pub. Date: Oct. 13, 2022

(54) METHODS, SYSTEMS, AND APPARATUS TO GENERATE LOGIC BASED THERMAL DEGRADATION ALERTS IN COMPUTE DEVICES

(71) Applicant: Intel Corporation, Santa Clara, CA (US)

(72) Inventors: Smit Kapila, Bangalore (IN); Abhishek Srivastav, Bangalore (IN); Sumod Cherukkate, Bangalore (IN); Manit Biswas, Udham Singh Nagar (IN); Zhongsheng Wang, Camas, WA (US); Bijendra Singh, Bangalore (IN); Deepak Ganapathy, Folsom, CA (US); Dipen Dudhat, Bengaluru (IN)

(21) Appl. No.: 17/850,561

(22) Filed: Jun. 27, 2022

(51) Int. Cl. G01K 11/22; H05K 7/20

(52) U.S. Cl. CPC G01K 11/22; H05K 7/20209; H05K 7/20172

(57) ABSTRACT

Methods, apparatus, systems, and articles of manufacture are disclosed to monitor thermal degradation of a compute device. One such method includes calculating, by executing instructions with processor circuitry, a thermal degradation value based on an equation, the equation generated based on testing of thermal interface materials having varying degrees of degradation. The method also includes comparing, by executing instructions with the processor circuitry, the thermal degradation value to a thermal degradation threshold to determine whether the thermal degradation threshold is satisfied, and, when the thermal degradation threshold is satisfied, triggering generation of a thermal degradation alert.

### FIELD OF THE DISCLOSURE

This disclosure relates generally to thermal degradation in compute devices and, more particularly, to methods, systems and apparatus to generate logic based thermal degradation alerts in compute devices.

### BACKGROUND

Operating compute devices generate heat that, unless dissipated, will adversely affect the performance of the devices. Ambient heat can add to this deleterious effect. In recent years, compute devices are designed to employ one or more heat dissipation techniques to effectively remove heat to thereby lower the operating temperature of the compute devices. Example ways that are currently used to perform heat dissipation include installed fans, strategic placement of one or more air vents that allow air to be released from a case of the compute device, incorporating a thermal interface material (TIM) between the silicon of the compute device and a heat sink device, etc.

### BRIEF DESCRIPTION OF THE DRAWINGS

FIG. 1 is a block diagram of an example compute device having an example thermal degradation monitor in accordance with the invention as disclosed herein.

FIG. 2 is a block diagram of a first example implementation of the example thermal degradation monitor of FIG. 1.

FIG. 3 is a block diagram of a second example implementation of the example thermal degradation monitor of FIG. 1.

FIG. 4 is an example graph illustrating an impact of blockage of a fan inlet/outlet on the speed of the fan.

FIG. 5 is an example graph illustrating test data used to derive a curve to predict fan speed when the fan inlet/outlet is blocked and test used to derive a curve to predict fan speed when the fan inlet/outlet is not blocked.

FIG. 6 is the graph of FIG. 5 including a clogged threshold region and an unclogged threshold region.

FIGS. 7A and 7B are tables illustrating example alert/alarm activations and example false alarm/alert detection.

FIG. 8 is a block diagram of an example TIM degradation sensor that can be used to implement at least a portion of the thermal degradation monitor of FIG. 1.

FIG. 9 is a TIM degradation Model.

FIG. 10 is a flowchart representative of example machine readable instructions and/or example operations that may be executed by example processor circuitry to implement the thermal degradation monitor of FIG. 2, FIG. 3, and/or FIG. 8.

FIG. 11 is a block diagram of an example processing platform including processor circuitry structured to execute the example machine readable instructions and/or the example operations of FIG. 10 to implement the thermal degradation monitor of FIG. 2, FIG. 3, and/or FIG. 8.

FIG. 12 is a block diagram of an example implementation of the processor circuitry of FIG. 11.

FIG. 13 is a block diagram of another example implementation of the processor circuitry of FIG. 11.

In general, the same reference numbers will be used throughout the drawing(s) and accompanying written description to refer to the same or like parts. The figures are not to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of a semiconductor device, “above” is not with reference to Earth, but instead is with reference to a bulk region of a base semiconductor substrate (e.g., a semiconductor wafer) on which components of an integrated circuit are formed. Specifically, as used herein, a first component of an integrated circuit is “above” a second component when the first component is farther away from the bulk region of the semiconductor substrate than the second component.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly that might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified in the below description. As used herein “substantially real time” refers to occurrence in a near instantaneous manner recognizing there may be real world delays for computing time, transmission, etc. Thus, unless otherwise specified, “substantially real time” refers to real time +/−1 second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “processor circuitry” is defined to include (i) one or more special purpose electrical circuits structured to perform specific operation(s) and including one or more semiconductor-based logic devices (e.g., electrical hardware implemented by one or more transistors), and/or (ii) one or more general purpose semiconductor-based electrical circuits programmable with instructions to perform specific operations and including one or more semiconductor-based logic devices (e.g., electrical hardware implemented by one or more transistors). Examples of processor circuitry include programmable microprocessors, Field Programmable Gate Arrays (FPGAs) that may instantiate instructions, Central Processor Units (CPUs), Graphics Processor Units (GPUs), Digital Signal Processors (DSPs), XPUs, or microcontrollers and integrated circuits such as Application Specific Integrated Circuits (ASICs). For example, an XPU may be implemented by a heterogeneous computing system including multiple types of processor circuitry (e.g., one or more FPGAs, one or more CPUs, one or more GPUs, one or more DSPs, etc., and/or a combination thereof) and application programming interface(s) (API(s)) that may assign computing task(s) to whichever one(s) of the multiple types of processor circuitry is/are best suited to execute the computing task(s).

### DETAILED DESCRIPTION

Methods, systems, and apparatus to generate logic based thermal degradation alerts in compute devices are disclosed herein. As described briefly above, heat dissipation is of critical importance to the proper operation and performance of compute devices. When heat build-up is allowed to occur in a compute device, operations may slow down, an exhaust fan installed in the compute device may become louder and/or remain on longer, the long term reliability of the compute device components may be adversely impacted, any processing units installed in the compute device may experience burn out, etc.

A variety of thermal solutions may be used to properly dissipate the heat and thereby prevent the adverse conditions described above. Some example thermal solutions include using a thermal interface material (TIM) disposed between, for example, an integrated circuit and a heat sink. The TIM provides a pathway for heat generated by the integrated circuit to be dispensed to the heat sink which is designed to dissipate the heat. In some examples, a thermal solution can include an exhaust fan located near a vent (e.g., outlet) on the casing of the compute device such that hot air within the casing can be released outside of the casing.

Unfortunately, TIM and fan-based thermal solutions each present challenges. For example, a solution that uses a TIM to direct heat away from an integrated circuit (IC) toward a heat sink dries out over time. When a TIM becomes too dry, it may begin to crumble and/or become detached from portions of the IC surface. This is a problem because as the TIM dries out, it is a less efficient heat conductor.

Consider, for example, that the IC surface is, at a microscopic level, rough. As a result, a TIM is usually somewhat malleable and thereby able to fill any crevices in the rough surface. As a result, there are few (if any) airgaps between the TIM and the surface of the IC. As air is an excellent insulator, minimizing the number air gaps is desirable for enhanced heat conduction. In contrast, a dry, crumbling, detaching TIM causes air gaps to form between the TIM and the surface of the IC resulting reduced heat conduction such that less heat reaches the heat sink and the temperature of the IC rises.

An exhaust fan operating within the casing of a new compute device and near a vent in the casing offers excellent heat dissipation as heat is directed by the fan from the interior of the casing to the exterior of the casing via the vent. However, over time, the vent and fan often become dusty. The dust, when thick enough, can clog the vent such that at least some of the hot air being directed by the fan to the vent is blocked by the dust and, thus, cannot be released efficiently. Insufficient release of the heat generated by the IC via the fan and outlet also causes the temperature of the IC to rise.

The methods, systems and apparatus disclosed herein generate logic based thermal degradation alerts in compute devices. Such methods, systems and apparatus operate based on a novel TIM degradation index (TGI). The TGI is developed using novel sensing and modeling methodologies. In some examples, the TGI is defined to be a function of a package power and package temperature. A compute device/processor typically includes different digital thermal sensors to measure the temperature. A “core temperature” is measured per core while a “package temperature” is a weighted average value of individual core temperatures reported by software monitoring applications. The “package power” refers to the power consumption of the entire CPU package.

In some examples, testing data and modeling is performed in a test environment to develop an equation to be used to calculate a TGI value. The equation is then supplied to the example thermal degradation monitors associated with example compute devices. Thus, for example, in the test environment, package temperature and package power values are measured from compute devices. Each such compute device has a thermal management system (e.g., a thermal interface material, a fan with an inlet/outlet (vent), a heat exchanger, a heat sink, etc.) that is in a different state of degradation. For example, package temperature data and package power data are collected from a first CPU having a new thermal management system, a second CPU having a lightly degraded thermal management system and a third having a heavily dried out (e.g., a heavily degraded) thermal management system. Thus, the power and temperature data is collected from each of the first, second and third CPUs each having the corresponding thermal management system described in the foregoing sentence. Based on that collected power and temperature data, modeling is performed to develop an equation to that can be used to calculate a TGI value.

The equation is supplied to example thermal degradation monitors for use in determining TGI values for corresponding compute devices when such compute devices are operating in the field. In some examples, a different equation may be derived for each of the differing TIMs. In some examples, the derived equation may take any form. In some examples, the derived equation takes a form that represents the impact of the package temperature, for example, on the package power. Thus, in some examples, the equation may identify a relationship between the package temperature and package power when the TIM is new, is lightly degraded, or is heavily degraded. Any constants included in the derived equation(s) are also supplied to the example thermal degradation monitors for use in determining TGI values based on real-time power package and/or power temperature values. In some examples, when the TGI value is to be generated, the TGI calculator places one of a sensed package temperature or a sensed package power into the equation and the results of the equation yield the other.

The thermal degradation monitors of the corresponding compute devices compare the respective TGI values calculated by the respective thermal degradation monitors to a TGI threshold. The TGI threshold is also derived from the testing described above and is typically developed using test data collected based on the thermal management system having the most heavily degraded thermal interface material (TIM). The threshold (which can be a line, a value, a curve) is also typically placed below in a position that is relative to a curve/line, etc., representing the conditions of a compute device having the most heavily degraded thermal management system. As a result, when the TGI threshold is crossed, the alert can be generated by the thermal degradation monitor well before conditions associated with (similar to) a heavily degraded thermal management system are reached. When any of the thermal degradation monitors determines that the respective TGI value has satisfied (and/or crossed) the TGI threshold, such thermal degradation monitors trigger generation of a thermal maintenance alert.

In some examples, the methods, systems and apparatus disclosed herein determine a fan inlet/outlet blocking index (“FIBI”) as a function of a package power, package temperature, fan speed, and skin temperature. In some examples, the collection of the skin temperature is optional. In some such examples, the package power, package temperature and fan speed are determined for compute devices having thermal management systems (wherein the thermal management systems can include a fan having an inlet/outlet (also referred to as a vent, among other things) that are in differing conditions of thermal degradation. For example, package temperature, package power values, and fan speeds (and in some cases skin temperature) are determined for a first CPU having a new thermal management system (e.g., a clean fan and vent(s) and/or inlet/outlet), a second CPU having mildly degraded thermal management system (e.g., a fan vent (also referred to as an inlet/outlet or an exhaust vent) that is lightly blocked and a third CPU having a heavily degraded thermal management system (e.g., a vent that is heavily blocked).

Modeling tools use the package power, package temperature and fan speeds collected in a test environment from the first, second, and third CPUs (or any desired number of CPUs) to develop a FIBI value equation that can be used to calculate a FIBI value. The thermal degradation monitor can use that equation when operating within a CPU in the field to determine a FIBI value for the operating CPU. The thermal degradation monitor then determines whether the calculated FIBI value has crossed (or otherwise satisfied) a FIBI threshold. When the FIBI threshold is satisfied, the thermal degradation monitor triggers a self-cleaning service and/or triggers generation of a thermal degradation alert/notification.

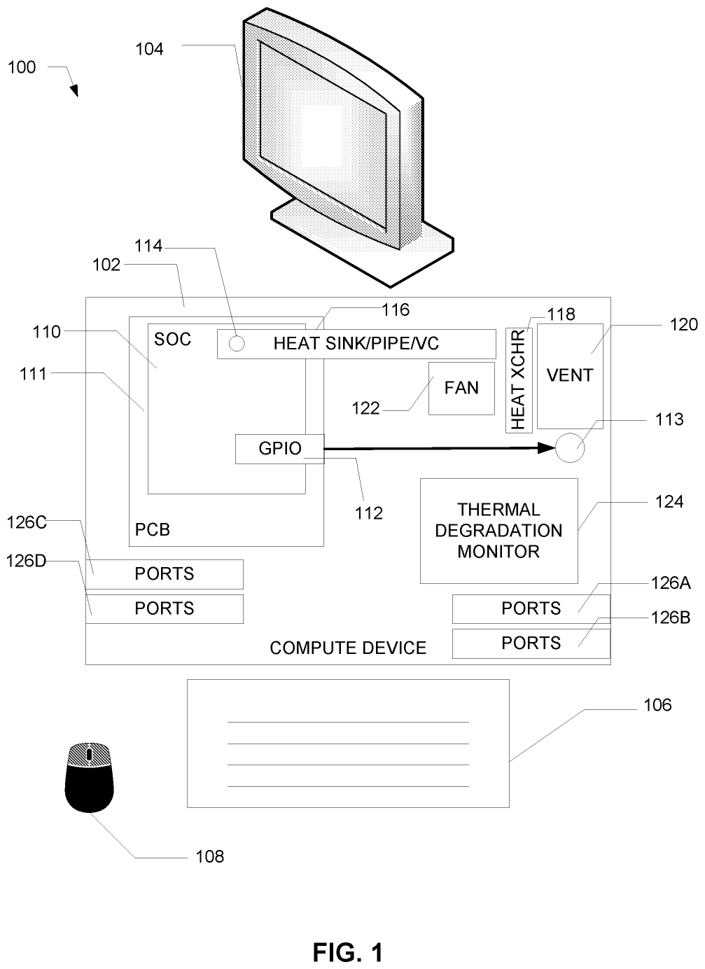

FIG. 1 is a block diagram 100 of an example compute device 102 that communicates with an example monitor 104 (e.g., an LCD monitor), an example keyboard 106 and an example mouse 108. In some examples, the compute device 102 includes an example system on a chip (“SOC”) 110 disposed on an example printed circuit board 111. The example SOC 110 includes (or is in communication with) an example general purpose input/output 112 that can actuate an example LED light 113. In some examples, an example thermal sensor 114 is in contact with the SOC 110 and an example heat sink/heat pipe/VC 116. The heat sink 116 provides a pathway for heat generated by the SOC 110 to be pulled away from the SOC 110 and directed to an example heat exchanger 118. In some examples, the heat exchanger 118 sheds heat through an example vent 120. In some examples, an example fan 122 directs warm air from an interior cavity of the compute device 102 to the heat exchanger 118 for subsequent exit from the interior cavity via the vent 120. Thus, the fan 122, the heat exchanger 118, the heat sink 116 and the vent 120 provide for the dissipation of heat from the compute device.

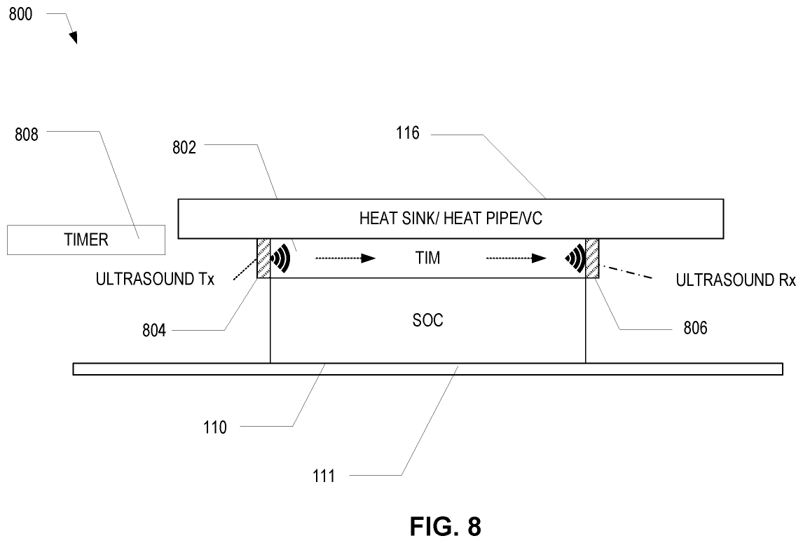

Although not illustrated in FIG. 1 due to the view of the compute device block diagram of FIG. 1, a thermal interface material (TIM) is disposed between the SoC (or any other type of silicon chip) and the heat sink 116 (of FIG. 1). The position of the TIM is shown in FIG. 8 and described in detail in connection with FIG. 8 below.

In some examples, the compute device 102 further includes an example thermal degradation monitor 124 to monitor thermal conditions of the compute device 102 as disclosed further herein and to generate one or more alerts when the thermal conditions meet or exceed (or otherwise satisfy) one or more desired thresholds. In some examples, the compute device 102 further includes example ports 126A, 126B, 126C, 126D which may be used for any of a variety of input/output purposes.

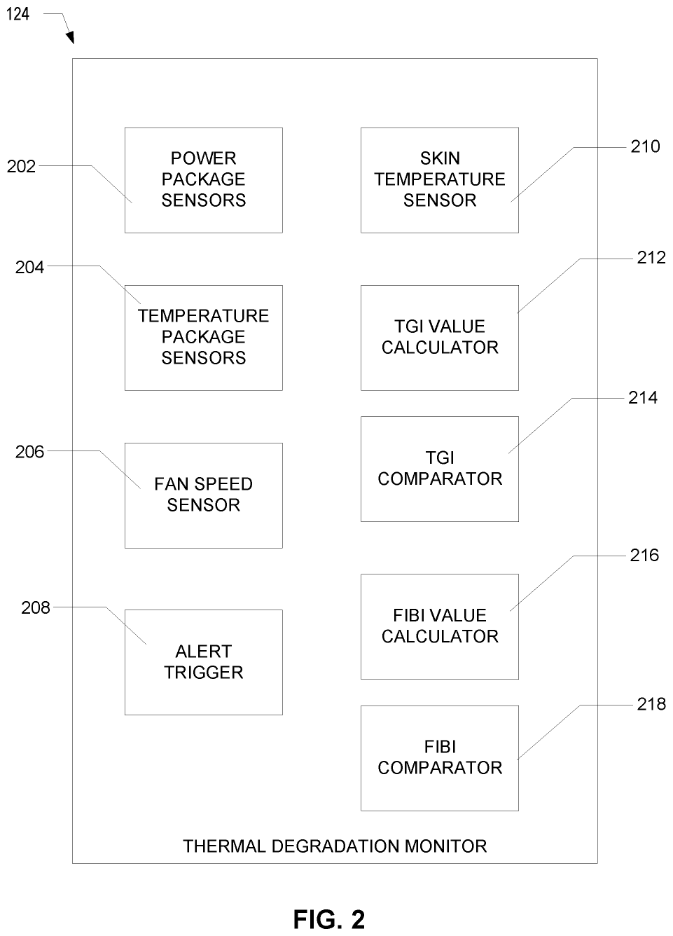

FIG. 2 is a block diagram of the example thermal degradation monitor of FIG. 1. The thermal degradation monitor 124 generates logic based thermal degradation alerts when temperature conditions associated with the computer device 102 (of FIG. 1) satisfy a threshold. The thermal degradation monitor of FIG. 2 may be instantiated (e.g., creating an instance of, bring into being for any length of time, materialize, implement, etc.) by processor circuitry such as a central processing unit executing instructions. Additionally or alternatively, the thermal degradation monitor of FIG. 1 and FIG. 2 may be instantiated (e.g., creating an instance of, bring into being for any length of time, materialize, implement, etc.) by an ASIC or an FPGA structured to perform operations corresponding to the instructions. It should be understood that some or all of the circuitry of FIG. 2 may, thus, be instantiated at the same or at different times. Some or all of the circuitry may be instantiated, for example, in one or more threads executing concurrently on hardware and/or in series on hardware. Moreover, in some examples, some or all of the circuitry of FIG. 2 may be implemented by microprocessor circuitry executing instructions to implement one or more virtual machines and/or containers.

In some examples, the example thermal degradation monitor 124 includes example package power sensors 202 (also referred to as package power sensor circuitry), example package temperature sensors (also referred to as package temperature sensors circuitry 204), an example fan speed sensor 206 (also referred to as fan speed sensor circuitry), an example alert trigger 208 (also referred to as alert generator circuitry), an example skin temperature sensor 210 (also referred to as skin temperature sensor circuitry), an example thermal interface material degradation index (TGI) value calculator 212 (also referred to as TGI calculator circuitry), an example TGI comparator 214 (also referred to as TGI comparator circuitry), an example fan inlet/outlet blocking index (FIBI) value calculator 216 (also referred to as FIBI value calculator circuitry), and an example FIBI comparator 218 (also referred to as FIBI comparator circuitry).

In some examples, during operation of the compute device 102, the example package power sensors 202 and the example package temperature sensors 204 collect package power values and package temperature values, respectively, for use by the example TGI valuate calculator 212. The TGI calculator 212 uses an equation generated based on testing data, as described above and described further below, to calculate a TGI value for the compute device based on, for example, the most recently collected package power values and package temperature values. The TGI value is provided to the example TGI comparator 214 which compares the TGI value to an example TGI threshold. In some examples, the TGI threshold is selected based on thermal conditions expected for the system. In some examples, the TGI value is based on the equation generated using the test data from the most heavily degraded thermal management system. In some examples, the equation defines a curve, line, etc. that represents the operation of the thermal management system (and the compute device in general) when the thermal management system is heavily degraded. In some such examples, a region of operation around the curve/line is to be avoided such that, any calculated TGI value that falls, example, above a lower boundary of the region of operation is assumed to be experiencing operation associated with a heavily degraded thermal management system. When, the TGI value satisfies the TGI threshold, the TGI comparator notifies the example alert trigger 208 which responds by generating one or more thermal degradation alerts/thermal maintenance alerts. Thus, when the TGI threshold value is satisfied, the compute device 102 is experiencing thermal conditions that are not conducive to proper and/or efficient operation of the compute device 102 such that thermal degradation is occurring or will occur if the potentially harmful/damaging thermal conditions persist. In some examples, as described above, when the TGI threshold value is satisfied, example thermal interface material (TIM) (described above) by which the example SOC 110 is coupled to the example heat sink 116 is drying out. When the TIM (see FIG. 8) is dried out there is a reduction in the amount of heat being conveyed from the SOC 110 (via the TIM) to the example heat sink 116. As a result, the current temperature of the SOC 110 is likely in excess of recommended operating temperatures. In some examples, the package power sensors 202, and the package temperature sensors 204 are configured to sense power and temperature, respectively, at periodic (or aperiodic) intervals. Likewise, in some examples, the TGI value calculator 212, periodically (or aperiodically) calculates and the TGI comparator 214 compares the calculated TGI values based on the most recently collected sensed information or based on one or more sets of the sensed information collected over different time periods (or in any other manner). As a result, the TGI value generally reflects a real time or near real time state of the thermal status of the SOC 110. As described above, the TGI value can be determined using the equation that was modeled based on the TIMs having varying degrees of degradation and plugging the recently sensed information into the equation, where appropriate.

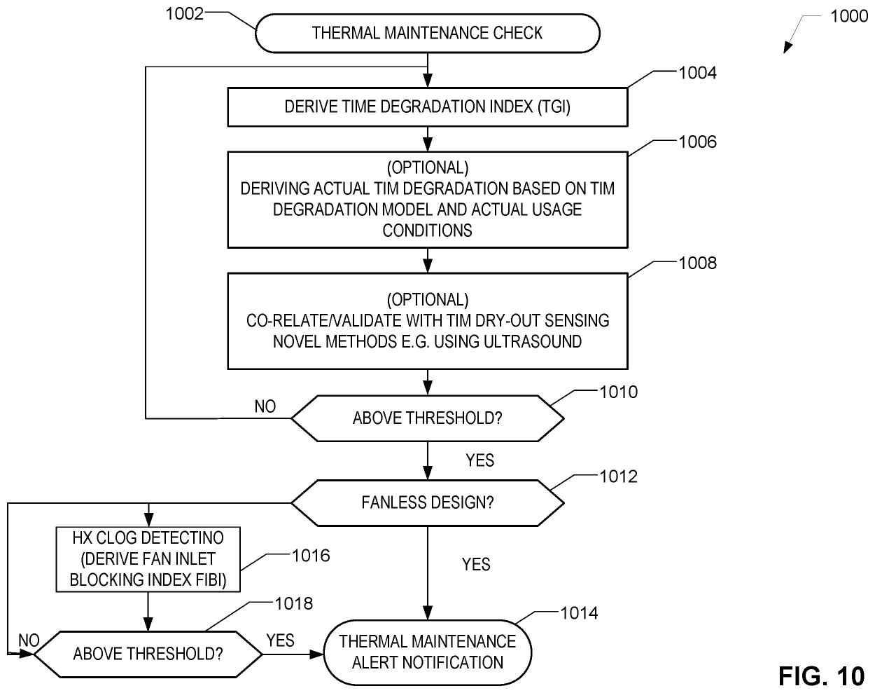

In some examples, one or more of the example package power sensor circuitry 202, the package temperature sensor circuitry 204, the TGI value calculator circuitry 212, the example TGI comparator circuitry 214 and/or the example alert trigger circuitry 208 is instantiated (in whole or in part) by processor circuitry executing sensing, calculating, comparing and alerting instructions, respectively, and/or configured to perform operations such as those represented by the flowchart of FIG. 10.

In some examples, during operation of the compute device 102, the example package power sensors 202, the example package temperature sensors 204, the example fan speed sensor 206, and the example skin temperature sensor 210 collect package power values, package temperature values, fan speeds, and skin temperatures, respectively, for use by the example FIBI value calculator 216. The FIBI calculator 216 uses an equation to calculate a FIBI value for the compute device 102 based on the foregoing data. The FIBI value is provided to the example FIBI comparator 218 which compares the FIBI value to an example FIBI threshold. As described above in connection with the TGI value and TGI threshold, the FIBI value is calculated using an equation generated using a modeling tool in a testing environment that is then pre-loaded into the example thermal degradation monitor. Similarly, one or more equations may be developed for use in determining a FIBI threshold in the testing environment. A region of operation near a curve/line generated based on an equation derived using test data collected from a compute device having heavily blocked fan inlet/outlet in the test environment is used to define the threshold. In some examples, the region of operation is selected such that a lower boundary of the region when crossed by a FIBI value will trigger generation of an alert before the fan inlet/outlet becomes heavily blocked/clogged. When, the calculated FIBI value satisfies the FIBI threshold, the FIBI comparator 218 notifies the example alert trigger 208 which responds by generating one or more thermal maintenance alerts or to by triggering initiation of a self-cleaning service.

Thus, when the FIBI threshold value is satisfied, the compute device 102 is experiencing thermal conditions that are not conducive to proper and/or efficient operation of the compute device 102 such that thermal degradation is occurring or will occur if the thermal conditions persist. In some examples, as described above, when the FIBI threshold value is satisfied, an example inlet/outlet of the example fan 122 (FIG. 1) (e.g., the example vent 120 (FIG. 1) (described above)) is likely clogged or otherwise adversely impacted by an accumulation of dust. As a result, the warm air inside the casing of the example computer device 102 (FIG. 1) is not being sufficiently vented. As a result, the heat within the compute device, the operating temperature of the SoC, etc., are likely in excess of recommended operating temperatures.

In some examples, one or more of the example package power sensor circuitry 202, the package temperature sensor circuitry 204, the example fan speed sensor circuitry 206, the example alert generator circuitry 208 the example FIBI value calculator circuitry 216, and/or the example FIBI comparator circuitry 218 is instantiated (in whole or in part) by processor circuitry executing sensing, calculating, comparing and alerting instructions and/or configured to perform operations such as those represented by the flowchart of FIG. 10.

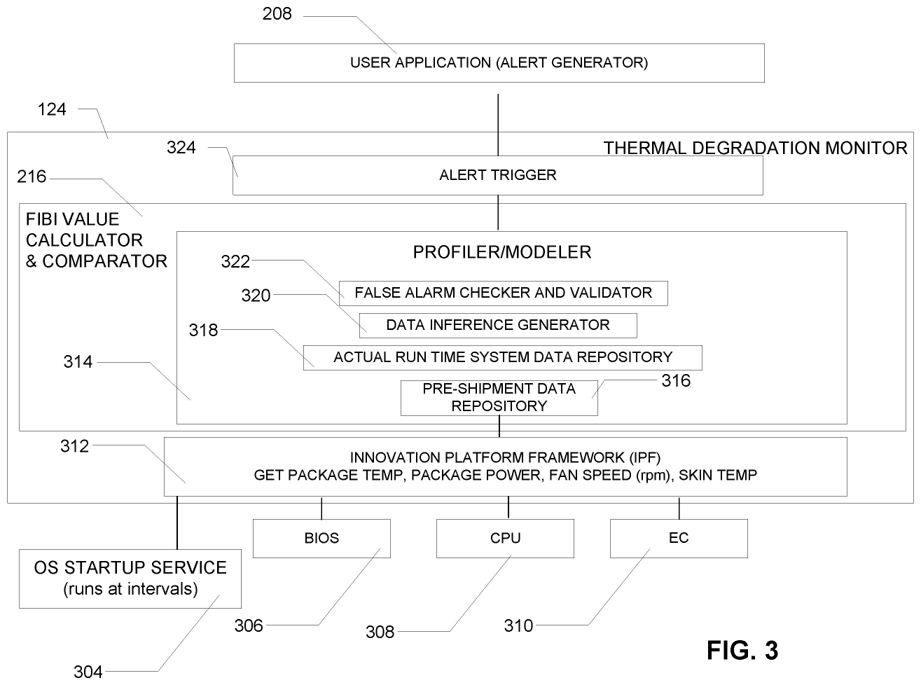

FIG. 3 is a block diagram of another example implementation of the example thermal degradation monitor 124 of FIG. 1 and FIG. 2. The thermal degradation monitor 124 of FIG. 3 is coupled to an example operating system (OS) startup service 304, an example basic input/output system (BIOS) 306, an example CPU 308, and an example embedded controller (EC) 310. In some examples, the thermal degradation monitor 124 includes an example innovation platform framework (IPF) 312 by which package temp, package power, fan speed and skin temperature data are collected and provided to the example FIBI calculator 216. The FIBI calculator 216 includes an example profiler/modeler 314 that includes an example pre-shipment data repository 316, an example runtime system data repository 318, an example data inference generator 320, an example false alarm checker/validator 322. An output supplied by the profiler/modeler 314 is supplied to an example alert trigger 324. In some examples, the alert trigger 324 of the thermal degradation monitor 124 (of FIG. 3) provides information (an output) to an example user application 208, which responds to the information by generating a thermal degradation alert, or initiating a self-cleaner, or taking any other number of appropriate actions). The output of the alert trigger 324 can be provided to the user application 208, when, for example, the profiler/modeler 314 has determined (via operation of the data inference generator 320 and the example false alarm checker/validator 322 and based on usage of the runtime data and the pre-shipment data) that a FIBI threshold has been satisfied. In some such examples, the user application 208 can respond to the output signal by generating an alert and/or triggering a self-cleaning operation (e.g., reversing fan rotation to unclog the fan vent).

Referring still to FIG. 3, the example IPF 312 collects information (including sensors information) from the example BIOS 306, the example CPU, and the example EC 310. In some examples, any of the package power, package temperature, fan speed, and/or skin temperature sensors described with respect to FIG. 2 may be accessed via the IPF 312. The IPF 312 supplies, to the example profiler/modeler 312, those aspects of the collected information that will be used to profile/model the impact of blockage of any portion of the fan inlet/outlet on the thermal conditions (e.g., changes in temperature, etc.) of the compute device 102. In some examples, data supplied by the IPF is directed to the example runtime system data repository 318.

The pre-shipment data repository 316 is pre-loaded (e.g., prior to shipment of the computer device 102) with data illustrating the impact of fan inlet/outlet blockage on the compute device 102 under various levels of blockage. In some examples, the pre-shipment data repository 316 holds data that is gathered by measuring the effects of fan blockage on the fan speed of: i) a first compute device that is new and has no fan inlet/outlet blockage, ii) a second compute device having a fan inlet/outlet that is partially blocked, iii) a third compute device having a fan inlet/outlet that is heavily blocked, etc. In some examples, the fan speeds needed, for example, to maintain the first, second and third compute devices (or components thereof) within an acceptable tolerance of a manufacturer designated temperature/temperature range are measured. In some examples, any of a variety of measurements related to the fan speeds and corresponding temperatures of each of the first, second, third, etc. compute devices can be recorded. The collected/measured data is used by a modeling tool to develop an equation that models a relationship between, for example, various fan speeds expected when the fan inlet/outlet is fully blocked/clogged and a duration of operating time, and a relationship between various fan speeds expected when the fan inlet/outlet is unblocked/unclogged and a duration of operating time.

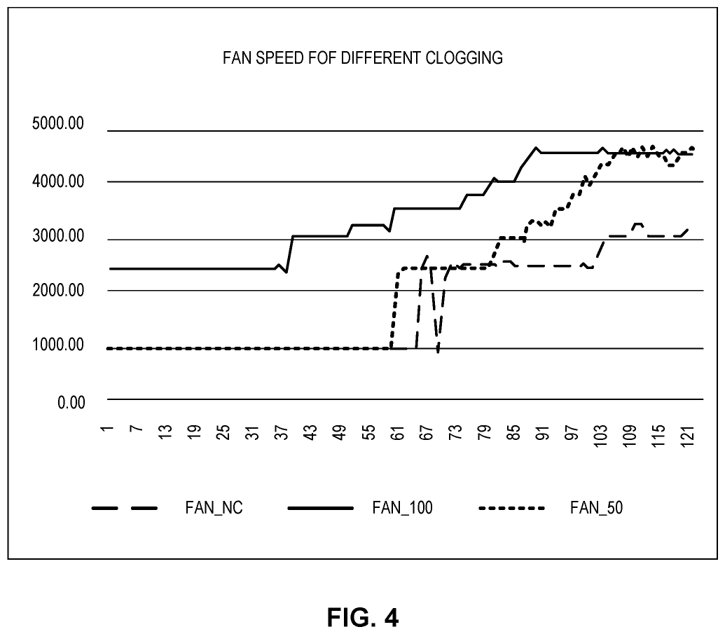

Referring now to FIG. 4, FIG. 4 is an example graph 400 illustrating example effects on fan speed of a compute device based on different amounts of blockage of a fan inlet/outlet. Data collected when the fan inlet/outlet is fully blocked is represented by the undashed line. Data collected when the fan inlet/outlet is partially blocked (e.g., 50% blocked) is represented by the dashed line having short dashes and data collected when the fan inlet/outlet is unblocked is represented by the dashed data line having longer dashes. Thus, the graph of FIG. 4 demonstrates that blockage of the fan inlet/outlet affects the fan speed, such that the fan speed increases with increased blockage in an effort to maintain, for example, an acceptable skin temperature, or any other desired metric.

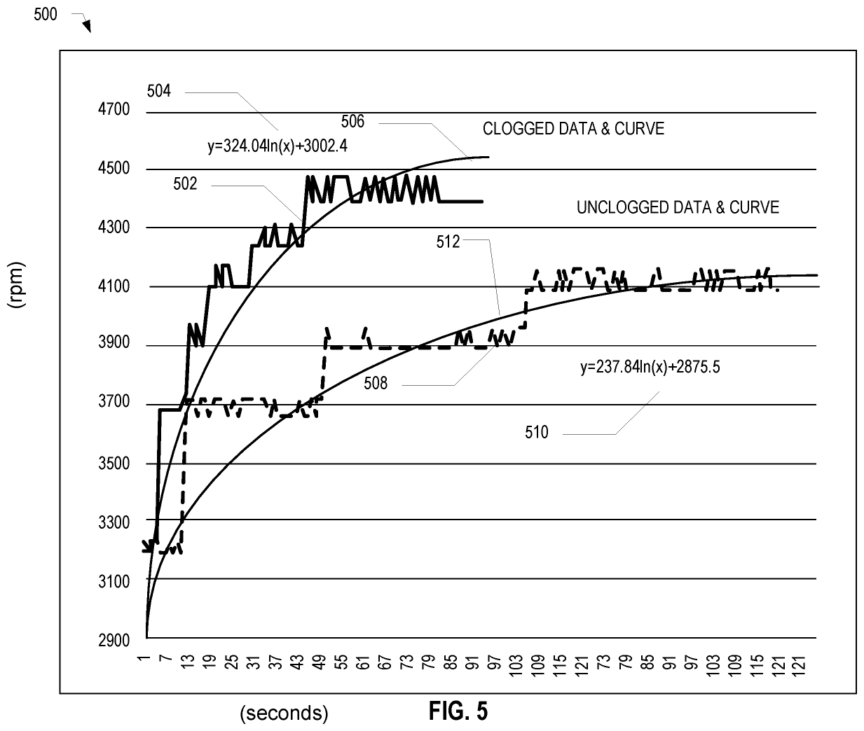

Referring also to FIG. 5, FIG. 5 is an example graph 500 illustrating example effects on fan speed of a compute device based on an amount of blockage of a fan inlet/outlet. Data collected when the fan inlet/outlet is blocked (blocked data 502), is modeled using a first equation 504 (e.g., y=3.2404 ln(x)+3002.4), where ln(x) represents the natural log of the variable x. In the first equation 504, y corresponds to the vertical axis and has units of rotations per minute (rpm) of the fan and x corresponds to the horizontal axis and has units of time (seconds). The first equation 504 results in a clogged curve 506 that represents the expected operation of the fan speed when the fan inlet/outlet is clogged/blocked. Data collected when the fan inlet/outlet is unblocked/unclogged (unblocked data 508), is modeled using a second equation 510 (e.g., y=237.84 ln(x)+2875.5). In the second equation 510, y corresponds to the vertical axis and has units of rotations per minute (rpm) of the fan and x corresponds to the horizontal axis and has units of time (seconds). The second equation 510 results in an unclogged curve 512 that represents the expected operation of the fan speed when the fan inlet/outlet is not clogged/blocked. The first equation 504 and the second equation 510 are examples equations derived by a modeling tool and loaded into the thermal degradation monitor (FIGS. 1, 2 and 3) before the corresponding compute device has shipped. In some examples, the modeling tool operates using any of a variety of modeling techniques and/or data inference techniques to analyze the collected data and determine an equation that represents the collected data.

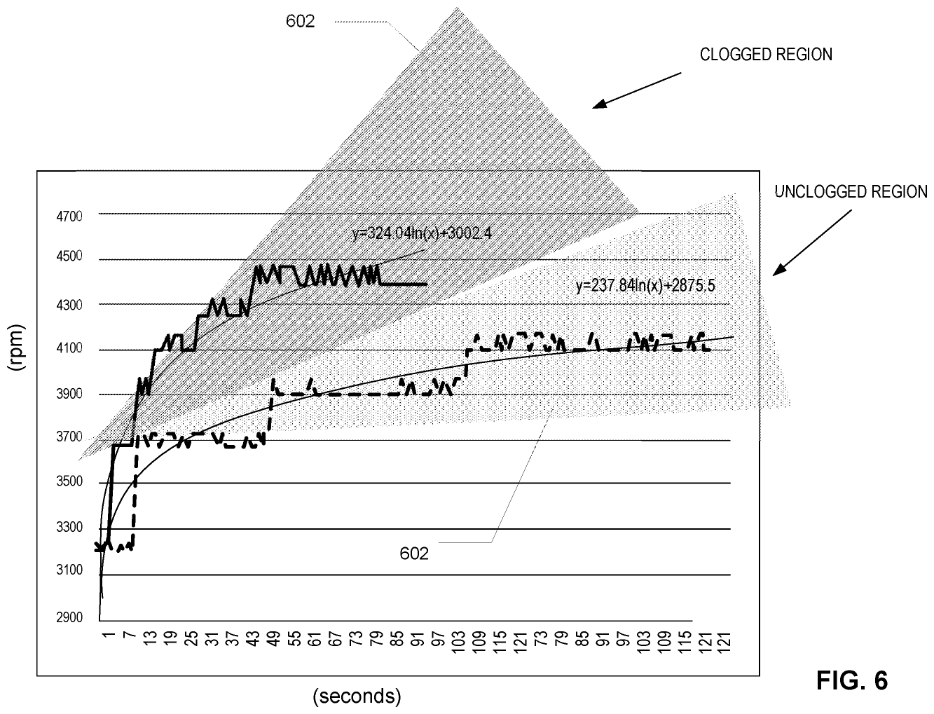

Referring now to FIG. 6, FIG. 6 is an example graph 600 that includes the information of the example graph 500 (FIG. 5) and additionally includes a clogged region 602 and an unclogged region 604. The clogged region 602 represents a region of operation corresponding to a compute device having a fan that is clogged. The clogged region 602 indicates that when a fan is operating on or near the clogged curve (see FIG. 5) (e.g., within the clogged region 602) the fan is likely clogged and action based on the clog should be taken (e.g., trigger generation of an alert and/or trigger self-cleaning). The unclogged region 604 indicates that when a fan is operating on or near the unclogged curve (see FIG. 5) (e.g., within the unclogged region 604) the fan is likely unclogged and no maintenance actions or alerts need to occur.

Referring again to FIG. 3, the example data inference generator 320 of the example profiler/modeler 314 uses the information stored in the pre-shipment data repository 316 (e.g., the equations and constants included in the equations) and additionally uses information collected during runtime of the compute device 102 (see FIG. 1) in which the thermal degradation monitor 124 is installed. As described above, the data collected during runtime is obtained by the example IPF 312 and supplied to the example actual runtime system data repository 318. The data inference generator 320 uses the pre-shipment equations and constants (as well any other information included therewith), and the runtime data to determine whether the FIBI value and to determine whether the FIBI threshold has been satisfied. In this manner, the data inference generator 320 operates not only as the example FIBI value calculator 216 (of FIG. 2) but also operates as the example FIBI comparator 218 (of FIG. 2).

In some examples, the lower boundary of the clogged region 602 (of FIG. 6) can be treated as the FIBI threshold. In some such examples, when the runtime data falls on or above the FIBI threshold, the example data inference generator 320 can notify the false alarm checker/validator which may perform any number of operations to determine whether the crossing of the FIBI threshold is to be treated as a false alarm and/or whether the crossing of the FIBI threshold is valid. Provided that the crossing does not represent a false alarm and is valid, the profiler/modeler 314 notifies the example alert trigger 324 which triggers the user application 208. The user application 208 responds by generating a maintenance alert (e.g., actuating an LED, causing a pop-up window to appear on the example monitor 104 (of FIG. 1), causing a speaker of the compute device 102 to generate a sound, etc.) and/or triggering/initiating a self-cleaning operation/mechanism.

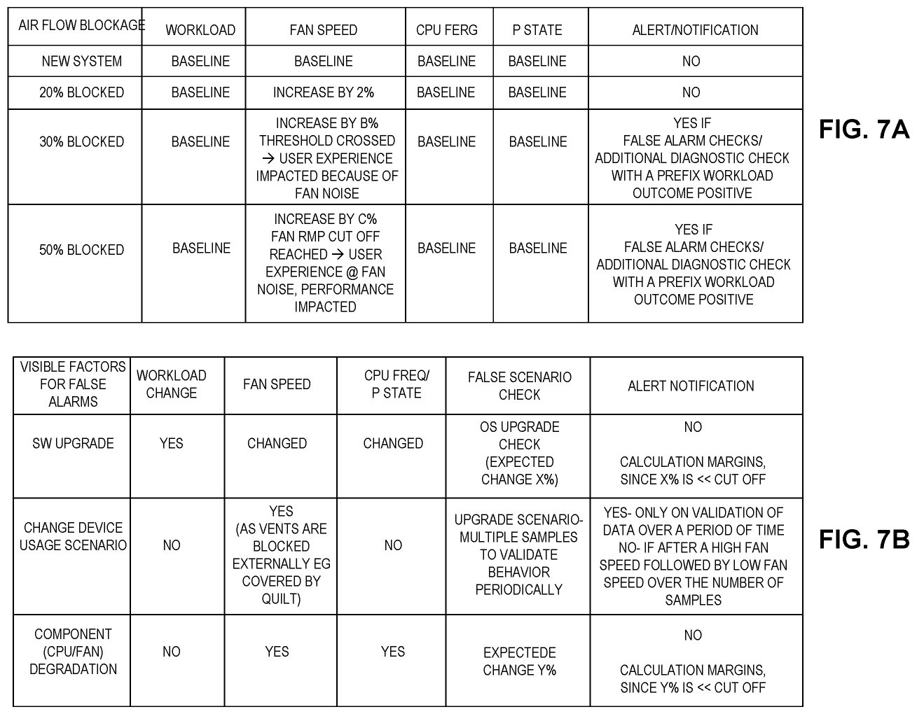

FIG. 7A and FIG. 7B are first and second tables 700A, 700B, respectively. The first table 700A, provides examples of how a blocked fan impacts the CPU and associated features/characteristics of operation. The rows of the first column (AIR FLOW BLOCKAGE) include different levels of air flow/vent (inlet/outlet) blockage that may occur. The rows of the second column (WORKLOAD) include an amount of workload applied to a CPU experiencing the levels of air flow blockage indicated on the same rows of the first column.

The rows of the third column (FAN SPEED) indicate speeds at which a fan of the CPU experiencing the levels of air flow blockage are operating. As illustrated by the information in the corresponding rows of column 1 and column 3, increases in blockage are associated with increases in fan speed such that an increase from no blockage to a 20% blockage causes the fan speed to increase by a desired percentage (wherein the desired percentage is represented by “a %”) that is likely to result in a fan speed that allows the CPU to continue operating within desired temperature levels, and/or power levels. When an increase in blockage of 30% is experienced by the fan vent/inlet/outlet, the fan speed is increased by “b %,” wherein b % represents a fan speed that is likely to allow the CPU fan to continue operating within desired parameters related to temperature, and/or power. At a 30% blockage, the user experience is likely negatively impacted by an increase in fan noise due to the increase in fan speed by b %, such that a 30% blockage corresponds to a FIBI threshold being satisfied. If such a FIBI threshold is indeed satisfied, the thermal degradation monitor (e.g., the example alert trigger 324 of FIG. 4, and/or the example alert trigger 208 of FIG. 2), as described above, triggers generation of an alert and/or initiation of a self-cleaning operation.

When an increase in blockage of 50% is experienced by the fan vent/inlet/outlet, the fan speed is increased by “c %,” wherein a c % increase is to result in a fan speed that is likely to allow the CPU associated with the blockage to continue operating within desired parameters related to temperature, and/or power. At a 50% blockage, the user experience is likely negatively impacted by an increase in fan noise due to the increase in fan speed, and a decrease in CPU performance. As such a 50% blockage corresponds to a FIBI threshold being satisfied. If such a FIBI threshold is indeed satisfied, the thermal degradation monitor, as described above, triggers an alert and/or a self-cleaning operation. Similarly, a fan speed increase of c % can correspond to a fan rpm cut off being reached.

The rows of the fourth column (CPU FREQ) provide frequencies at which the CPU is operating when the CPU is experiencing the amount of vent/inlet/outlet blockage of the corresponding rows of column 1. As illustrated, the CPU is able to maintain a baseline frequency for the various levels of fan blockage until the level of fan blockage is at 50% at which time, the CPU operating frequency is impacted. Such an impact on the frequency is expected to cause the operating frequency to slow.

The rows of the fifth column (P STATE) provide a performance states of the CPU when the CPU is experiencing the amount of vent/inlet/outlet blockage of the corresponding rows of column 1. As shown in the data of the fifth column, the CPU maintains a baseline performance state for the various levels of fan blockage until the level of fan blockage is at 50% at which time, the CPU performance state is impacted. Such an impact on the p state is expected to be a negative impact on the performance state of the CPU.

The rows of the sixth (ALERT/NOTIFICATION) provide an indication as to whether the example thermal degradation monitor will trigger an alert or other operation when the CPU is experiencing the amount of vent/inlet/outlet blockage of the corresponding rows of column 1. As shown in the data of the sixth column, the thermal degradation monitor of the CPU does not trigger an alert until the fan blockage reaches 30%, provided that, when the fan blockage is 30%, a false alarm check and or any other additional diagnostic check with a prefix workload outcome is positive. Likewise, the thermal degradation monitor of the CPU triggers an alert when the fan blockage reaches 50%, provided that, a false alarm check and or any other additional diagnostic check with a prefix workload outcome is positive.

The table 2 700B of FIG. 7B, includes six columns corresponding to: 1) “Possible factors for False Alarms,” 2) “Workload Change,” 3) “Fan Speed,” 4) “CPU Freq/P State,” 5) “False Scenario Check,” and 6) “Alert Notification.” The table 2 700B is intended to illustrate 3 possible scenarios that can result in a false alert/alarm being triggered including: 1) an operating system/software upgrade, 2) an undesirable usage scenario (e.g., the compute device is located on a bed, table or other surface that blocks the fan), and 3) the components of the compute device (e.g., the CPU, the FAN, etc.) are degraded. The information in the rows of columns 2-6 of table 2 700B describe ways in which various characteristics of the compute device can be affected by the occurrence of such scenarios.

In some examples, the example thermal degradation monitor 124 of FIG. 3 can be modified to perform the operations performed by the example TIM value calculator 212 and the example TMI comparator 214. In some such examples, the IPF 312 collects package power data, and package temperature data and supplies the collected data to the example actual runtime system data repository 318. (It is noted that the data is described as “actual” to distinguish the data as collected during runtime versus being collected in a test environment.) Likewise, the example pre-shipment data repository 316 can be populated with data illustrating how the package power affects the package temperature under different conditions, e.g., under conditions in which the: i) thermal interface material TIM is new, ii) the TIM is moderately dried out, and iii) the TIM is very dried out. In some such examples, a modeling tool and data inference tool can use the collected data to determine an equation that can be used to represent the expected effects TIM degradation on package power and/or package data. In some such examples, the data inference generator 320 (of FIG. 3) uses data inference tools and/or data modeling tools to, based on the runtime data and the pre-shipment data, calculate the TGI value and determine whether the TGI value is satisfied. In some such examples, the example false alarm checker and validator 322 can perform operations similar to those described with reference to the table 1 and the table 2 of FIG. 7 to determine whether the TGI is not actually satisfied (e.g., a false alarm is present) and to determine the validity of the satisfaction of the TGI.

In some examples, the example compute device 102 can include two different implementations of the thermal degradation monitor 124 of FIG. 3, wherein one implementation of the thermal degradation monitor 124 of FIG. 3 is configured to monitor the fan speed and blockage of the fan and another implementation of the thermal degradation monitor 124 of FIG. 3 is configured to monitor the package power and the package temperature. In some examples, the thermal degradation monitor 124 of FIG. 3, can be configured to perform operations to monitor the fan and blockage thereof (in the manner described above) and to perform operations to monitor the package power and package temperature (as described above) to determine an amount of degradation of the TIM of the compute device, and/or other aspects of the thermal dissipation tools installed in the example compute device 102 (of FIG. 1).

Referring now to FIG. 8, FIG. 8 is a block diagram 800 of the SoC 110 (of FIG. 1) and its position relative to the example printed circuit board 111 (of FIG. 1). In addition, the block diagram 800 includes a TIM 802 having one surface of the TIM 802 in contact with a surface of the SoC 110 and having another (opposite) surface of the TIM in 802 contact with the example heat sink/heat pipe/VC 116 (see also FIG. 1). An example ultrasound transmitter 804 is attached (or otherwise in contact with) one side of the TIM 802 and an example ultrasound receiver 806 is attached (or otherwise in contact with) an opposite side of the TIM 802. In some examples, the ultrasound transmitter 804 and the ultrasound receiver 806 cooperate to function as an example TIM degradation sensor 804/806 to sense an amount/level of degradation of the TIM 802.

In some examples, the example TIM degradation sensor 804/806 determines a level/amount of degradation of the example TIM 802 when the example ultrasound transmitter 804 transmits an ultrasound signal through the TIM 802. The ultrasound signal is captured at the example ultrasound receiver 806 after an amount of time. Generally, when the TIM 802 is fresh/new, the TIM 802 is somewhat malleable and has a consistency non unlike a gel. As the TIM 802 degrades, the TIM 802 hardens and becomes solid or more or at least more solid than when the TIM 802 is fresh/new. The time of travel of the ultrasound signal through the TIM 802, when the TIM is fresh/new will be faster. As the TIM degrades, the time of travel of the ultrasound signal through the TIM 802 will increase. Thus, in some examples, the TIM sensor 804/806 operates to determine a level of degradation of the TIM 802 based on the speed of the ultrasound signal through the TIM 802 (e.g., the time of arrival of the ultrasound signal at the receiver relative to the time of transmission). In some examples, an example timer 808 communicates with both the ultrasound transmitter 804 and the ultrasound receiver 806 to determine a time of arrival (e.g., a flight time) of an ultrasound signal emitted by the ultrasound transmitter 804 and received at the ultrasound receiver 806. In some examples, the timer 808 is disposed in the SoC 110, on the PCB 111, on an interior wall of a case of the compute device 102, or at any other place relative to the SoC 110.

In some examples, to determine expected times of arrival for a fresh TIM, a moderately degraded TIM, a heavily degraded TIM, etc., are determined experimentally by the manufacturer using compute devices having TIMs with varying levels of degradation and collecting information from TIM degradation sensor 804/806 information resulting from the transmission of ultrasound signals through the TIM 802. The time of arrival data resulting from the experimentation can be used by a modeling tool/data inference tool to determine an equation, or equations, that reflect the impact of various degradation levels of the TIM on the time of arrival data. Thus, when installed in the compute device (e.g., the compute device 102 of FIG. 1), the equation(s) can be used along with time of arrival data collected during runtime of the compute device to determine an amount of degradation of the TIM 802. In some examples, information about the amount of degradation of the TIM 802 can be taken into consideration by the profiler/modeler 314 of FIG. 3 when determining whether the TGI threshold has been satisfied. Or, the information about the amount of degradation of the TIM 802 can be used as an additional piece of information that can be used to validate an alert/alarm or validate a threshold crossing. In some examples, the information about the amount of degradation of the TIM 802 can be used to trigger an alert indicating that the TIM 802 is in need of repair/replacement. In some such examples, the example IPF 312 (see FIG. 3) can be configured to collect information supplied by the TIM degradation sensor 804/806.

Alternately, the ultrasound transmitter/receiver 804/806 of the example TIM degradation sensor can be replaced with a sensor configured to determine a capacitive response of TIM with age. That information can then be correlated to derive an amount of TIM degradation associated with the TIM 802 (FIG. 8) based on the age of the TIM. In some such examples, the amount of TIM degradation may also be based on an average workload demand on the compute device in which the TIM 802 is disposed.

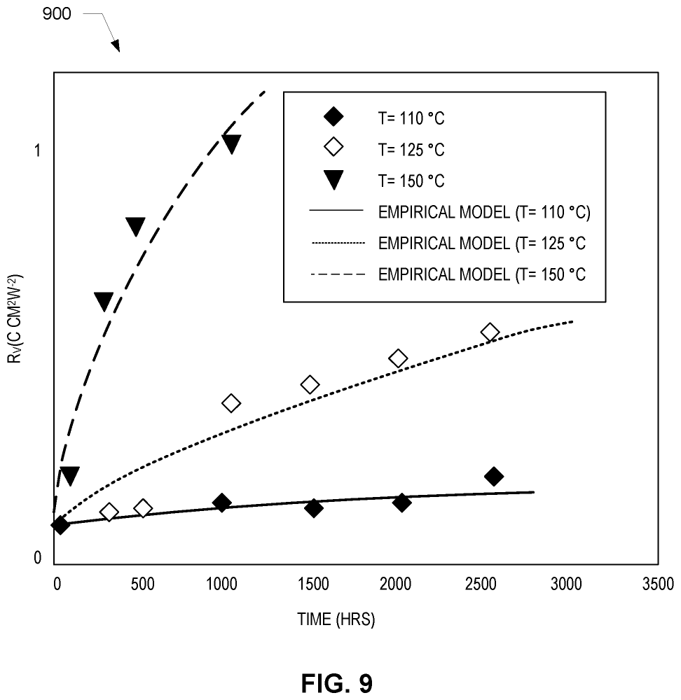

Referring to FIG. 9, FIG. 9 is an example graph 900 of illustrating an available TIM degradation Model. In some examples, TIM degradation predictions generated based on the TIM degradation Model of FIG. 9 along with the TIM drying sensing methodology, can be used to assess and validate TIM dry-outs. In some such examples, the example thermal degradation monitor can be configured to perform the assessment and validation of the amount of TIM dry-out/degradation.

While example manners of implementing the thermal degradation monitor 124 of FIG. 1 is illustrated in FIG. 2, FIG. 3, and in FIG. 8, one or more of the elements, processes, and/or devices illustrated in FIG. 2, FIG. 3, and/or FIG. 8 may be combined, divided, re-arranged, omitted, eliminated, and/or implemented in any other way. Further, the example package power sensors 202, the example package temperature sensors, the example fan speed sensor 206, the example alert generator 208, the example skin temperature sensor 210, the example thermal interface material degradation index (TGI) value calculator 212, the example TGI comparator 214, the example fan inlet/outlet blocking index (FIBI) value calculator 216, the example FIBI comparator 218, the example innovation platform framework (IPF) 312, the example profiler/modeler 314, the example pre-shipment data repository 316, the example actual runtime system data repository 318, the example data inference generator 320, the example false alarm checker/validator 322, the alert trigger 324, the example ultrasound transmitter 804 (see FIG. 8), the example ultrasound transceiver 806 (see FIG. 8),the example timer 808 (see FIG. 8), and/or, more generally, the example thermal degradation monitor 124 of FIG. 1, may be implemented by hardware alone or by hardware in combination with software and/or firmware. Thus, for example, any of the example package power sensors 202, example package temperature sensors, the example fan speed sensor 206, the example alert generator 208, the example skin temperature sensor 210, the example thermal interface material degradation index (TGI) value calculator 212, the example TGI comparator 214, the example fan inlet/outlet blocking index (FIBI) value calculator 216, the example FIBI comparator 218, the example innovation platform framework (IPF) 312, the example profiler/modeler 314, the example pre-shipment data repository 316, the example actual runtime system data repository 318, the example data inference generator 320, the example false alarm checker/validator 322, the example alert trigger 324, the example ultrasound transmitter 804 (see FIG. 8), the example ultrasound transceiver 806 (see FIG. 8), the example timer 808 (see FIG. 8), and/or, more generally, the example thermal degradation monitor 124, could be implemented by processor circuitry, analog circuit(s), digital circuit(s), logic circuit(s), programmable processor(s), programmable microcontroller(s), graphics processing unit(s) (GPU(s)), digital signal processor(s) (DSP(s)), application specific integrated circuit(s) (ASIC(s)), programmable logic device(s) (PLD(s)), and/or field programmable logic device(s) (FPLD(s)) such as Field Programmable Gate Arrays (FPGAs). Further still, the example thermal degradation monitor 124 of FIG. 1 may include one or more elements, processes, and/or devices in addition to, or instead of, those illustrated in FIG. 2, FIG. 3, and in FIG. 8, and/or may include more than one of any or all of the illustrated elements, processes and devices.

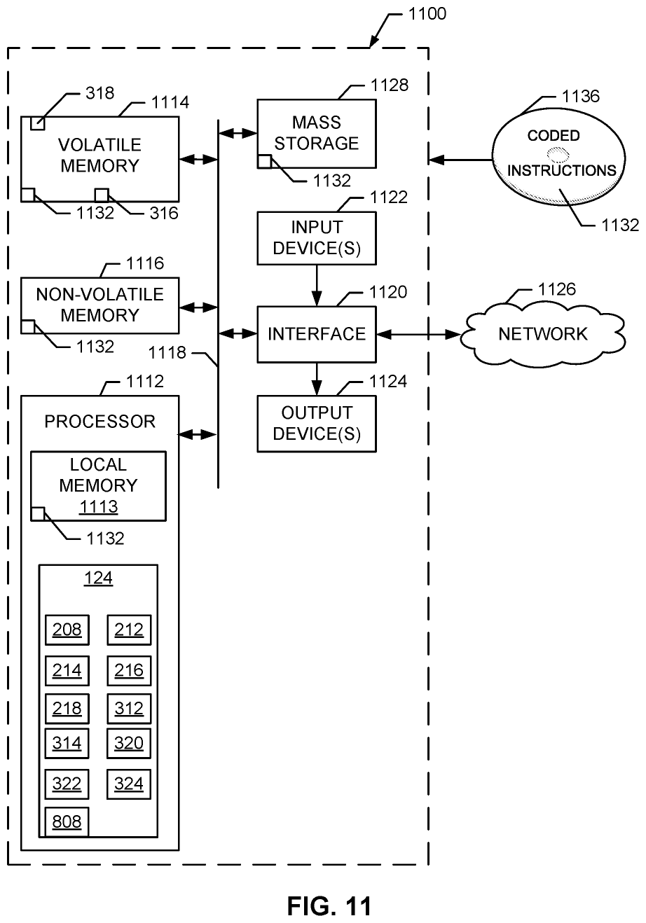

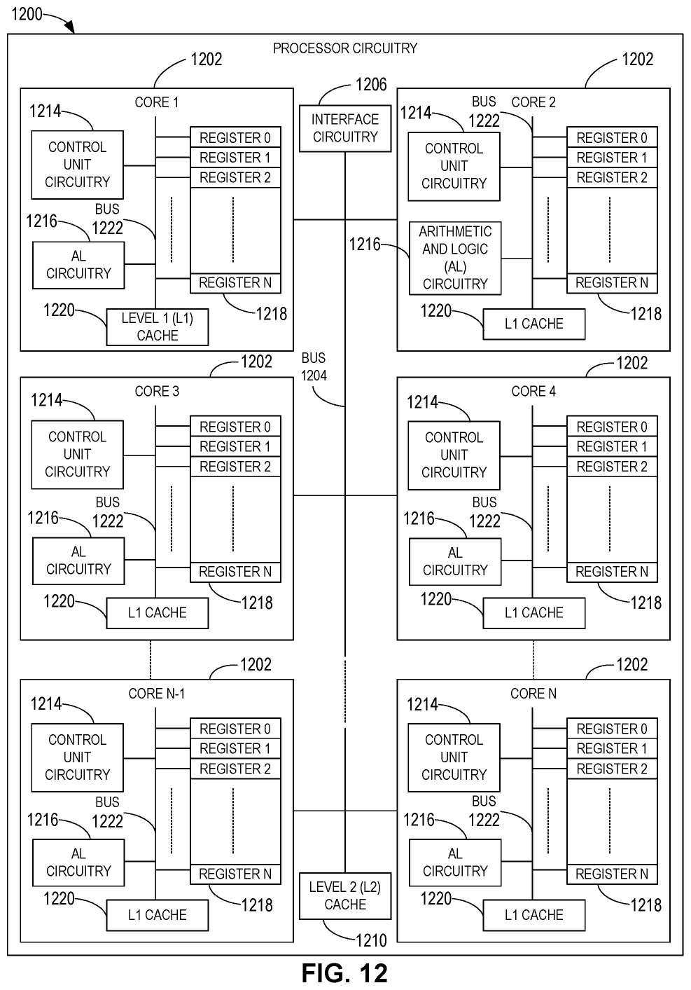

A flowchart representative of example machine readable instructions, which may be executed to configure processor circuitry to implement the thermal degradation monitor 124 of FIG. 2, FIG. 3, and/or FIG. 8, is shown in FIG. 10. The machine readable instructions may be one or more executable programs or portion(s) of an executable program for execution by processor circuitry, such as the processor circuitry 1112 shown in the example processor platform 1100 discussed below in connection with FIG. 11 and/or the example processor circuitry discussed below in connection with FIGS. 12 and/or 13. The program may be embodied in software stored on one or more non-transitory computer readable storage media such as a compact disk (CD), a floppy disk, a hard disk drive (HDD), a solid-state drive (SSD), a digital versatile disk (DVD), a Blu-ray disk, a volatile memory (e.g., Random Access Memory (RAM) of any type, etc.), or a non-volatile memory (e.g., electrically erasable programmable read-only memory (EEPROM), FLASH memory, an HDD, an SSD, etc.) associated with processor circuitry located in one or more hardware devices, but the entire program and/or parts thereof could alternatively be executed by one or more hardware devices other than the processor circuitry and/or embodied in firmware or dedicated hardware. The machine readable instructions may be distributed across multiple hardware devices and/or executed by two or more hardware devices (e.g., a server and a client hardware device). For example, the client hardware device may be implemented by an endpoint client hardware device (e.g., a hardware device associated with a user) or an intermediate client hardware device (e.g., a radio access network (RAN)) gateway that may facilitate communication between a server and an endpoint client hardware device). Similarly, the non-transitory computer readable storage media may include one or more mediums located in one or more hardware devices. Further, although the example program is described with reference to the flowchart illustrated in FIG. 10, many other methods of implementing the example thermal degradation monitor 124 of FIG. 2, FIG. 3, and FIG. 8 may alternatively be used. For example, the order of execution of the blocks may be changed, and/or some of the blocks described may be changed, eliminated, or combined. Additionally or alternatively, any or all of the blocks may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The processor circuitry may be distributed in different network locations and/or local to one or more hardware devices (e.g., a single-core processor (e.g., a single core central processor unit (CPU)), a multi-core processor (e.g., a multi-core CPU, an XPU, etc.) in a single machine, multiple processors distributed across multiple servers of a server rack, multiple processors distributed across one or more server racks, a CPU and/or a FPGA located in the same package (e.g., the same integrated circuit (IC) package or in two or more separate housings, etc.).

The machine readable instructions described herein may be stored in one or more of a compressed format, an encrypted format, a fragmented format, a compiled format, an executable format, a packaged format, etc. Machine readable instructions as described herein may be stored as data or a data structure (e.g., as portions of instructions, code, representations of code, etc.) that may be utilized to create, manufacture, and/or produce machine executable instructions. For example, the machine readable instructions may be fragmented and stored on one or more storage devices and/or computing devices (e.g., servers) located at the same or different locations of a network or collection of networks (e.g., in the cloud, in edge devices, etc.). The machine readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine readable instructions may be stored in multiple parts, which are individually compressed, encrypted, and/or stored on separate computing devices, wherein the parts when decrypted, decompressed, and/or combined form a set of machine executable instructions that implement one or more operations that may together form a program such as that described herein.

In another example, the machine readable instructions may be stored in a state in which they may be read by processor circuitry, but require addition of a library (e.g., a dynamic link library (DLL)), a software development kit (SDK), an application programming interface (API), etc., in order to execute the machine readable instructions on a particular computing device or other device. In another example, the machine readable instructions may need to be configured (e.g., settings stored, data input, network addresses recorded, etc.) before the machine readable instructions and/or the corresponding program(s) can be executed in whole or in part. Thus, machine readable media, as used herein, may include machine readable instructions and/or program(s) regardless of the particular format or state of the machine readable instructions and/or program(s) when stored or otherwise at rest or in transit.

The machine readable instructions described herein can be represented by any past, present, or future instruction language, scripting language, programming language, etc. For example, the machine readable instructions may be represented using any of the following languages: C, C++, Java, C#, Perl, Python, JavaScript, HyperText Markup Language (HTML), Structured Query Language (SQL), Swift, etc.

As mentioned above, the example operations of FIG. 10 may be implemented using executable instructions (e.g., computer and/or machine readable instructions) stored on one or more non-transitory computer and/or machine readable media such as optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms non-transitory computer readable medium, non-transitory computer readable storage medium, non-transitory machine readable medium, and non-transitory machine readable storage medium are expressly defined to include any type of computer readable storage device and/or storage disk and to exclude propagating signals and to exclude transmission media. As used herein, the terms “computer readable storage device” and “machine readable storage device” are defined to include any physical (mechanical and/or electrical) structure to store information, but to exclude propagating signals and to exclude transmission media. Examples of computer readable storage devices and machine readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine readable instructions, etc., and/or manufactured to execute computer readable instructions, machine readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements or method actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 10 is a flowchart representative of example machine readable instructions and/or example operations 1000 that may be executed and/or instantiated by processor circuitry to monitor thermal degradation of a compute device. The machine readable instructions and/or the operations 1000 of FIG. 10 begin at block 1002, at which the example thermal degradation monitor 124 begins to operate. In some examples, the thermal degradation monitor 124 begins to operate based on, for example, a notification from the example OS Startup Service 304 of FIG. 3. In some examples, the thermal degradation monitor 124 begins to operate when the compute device 102 of FIG. 1 begins to operate. At a block 1004, the example profiler/modeler 314 uses pre-shipped data, runtime data collected from sensors and a model/equation derived to calculate the TGI value. In some examples, the example TGI value calculator 212 operates to calculate the TGI value based on the equation, a set of constants included with the equation and runtime data. At a block 1006, the example TIM degradation monitor 804/806 of FIG. 8 operates with the example data inference generator 320 (FIG. 3) of the example modeler/profiler 314 of FIG. 3 to determine an amount of TIM degradation based on a TIM degradation model (see graph 900 of FIG. 9) as well as runtime sensor data indicating the current usage conditions of the compute device 102. At a block 1008, the example false alarm checker and validator 322 (FIG. 3) validates the example amount of TIM degradation by co-relating the amount of TIM degradation determined at the block 1006 with a second amount of TIM degradation obtained using the thermal degradation monitor 804/806 based on, for example, ultrasound signal flight times. When the two amount of TIM degradation are within a desired tolerance of each other, the amount of TIM degradation determined at the block 1006 is valid. At a block 1010, the example amount of TIM degradation is compared to a threshold amount of TIM degradation. Preferably, the threshold amount of TIM degradation, when satisfied, indicates that the TIM is in a state of degradation that is sufficiently poor to take action and/or trigger generation of an alert. When it is determined that the TIM degradation value is not satisfied, the flowchart returns to the block 1004, and the blocks subsequent thereto, as described above. When it is determined, at the block 1010, that the TIM degradation value is satisfied, the thermal degradation monitor 124 determines whether the compute device 102 is fanless (see block 1012). When the compute device 102 is fanless, the example alert generator 208 of FIG. 2 (or the example alert trigger 324 and the example user application 208 of FIG. 3 generates a thermal maintenance alert (at a block 1014). In some examples, after the alert is generated, the flowchart 1000 ends or is repeated as needed to continue to monitor thermal degradation. When, at the block 1012, the compute device 102 is determined to NOT be fanless (e.g., the compute device includes a fan), the example FIBI value calculator 216 (FIG. 2) or the example data inference generator 320 of the FIBI calculator 216 of FIG. 3, determines/calculates the FIBI value for the compute device 102 (at a block 1016). In some examples, the example FIBI comparator 218 (FIG. 2) or the example data inference generator 320 (FIG. 3) determines whether the FIBI threshold is satisfied by the FIBI value (at a block 1018). When the FIBI threshold is satisfied, the maintenance alert and/or a self-cleaning operation is triggered (block 1014). When the FIBI threshold is not satisfied, example FIBI value calculator 216 (FIG. 2) or the example data inference generator 320 of the FIBI calculator 216 of FIG. 3, again determines/calculates the FIBI value for the compute device 102 (at the block 1016) and the thermal degradation monitor 124 continues to the blocks subsequent thereto as described above. Thus, the thermal degradation monitor can determine that the TIM is degraded but, provided there is a fan included in the compute device, the thermal degradation monitor can rely on the fan to keep the compute device (e.g., the components thereof) sufficiently cool. When the fan becomes blocked such that the compute device is no longer sufficiently cool, the thermal degradation trigger generation of an alert.

In some examples, either the TIM degradation index can be used to determine whether an alert is to be triggered or the fan blockage index can be used, independently to be determine whether an alert is to be triggered.

FIG. 11 is a block diagram of an example processor platform 1100 structured to execute and/or instantiate the machine readable instructions and/or the operations of FIG. 10 to implement the thermal degradation monitor 124 of FIG. 2, FIG. 3 and FIG. 8. The processor platform 1100 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing device.

The processor platform 1100 of the illustrated example includes processor circuitry 1112. The processor circuitry 1112 of the illustrated example is hardware. For example, the processor circuitry 1112 can be implemented by one or more integrated circuits, logic circuits, FPGAs, microprocessors, CPUs, GPUs, DSPs, and/or microcontrollers from any desired family or manufacturer. The processor circuitry 1112 may be implemented by one or more semiconductor based (e.g., silicon based) devices. In this example, the processor circuitry 1112 implements components of the thermal degradation monitor 124 including the example alert generator 208, the example thermal interface material degradation index (TGI) value calculator 212, the example TGI comparator 214, the example fan inlet/outlet blocking index (FIBI) value calculator 216, the example FIBI comparator 218, at least a portion of the example innovation platform framework (IPF) 312, the example profiler/modeler 314, the example data inference generator 320, the example false alarm checker/validator 322, the alert trigger 324, and/or the example timer 808 (see FIG. 8).

The processor circuitry 1112 of the illustrated example includes a local memory 1113 (e.g., a cache, registers, etc.). The processor circuitry 1112 of the illustrated example is in communication with a main memory including a volatile memory 1114 and a non-volatile memory 1116 by a bus 1118. The volatile memory 1114 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1116 may be implemented by flash memory and/or any other desired type of memory device. Access to the main memory 1114, 1116 of the illustrated example is controlled by a memory controller 1117. In some examples, portions of the main memory 1114, 1116, may be used to implement the example pre-shipment data repository 316, and the example actual runtime system data repository 318. Or, in some examples, the mass storage 1128 of FIG. 11 may be used to implement the example pre-shipment data repository 316, and the example actual runtime system data repository 318.

The processor platform 1100 of the illustrated example also includes interface circuitry 1120. The interface circuitry 1120 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface. In some examples, the interface circuitry 1120 is implemented with the example innovation platform (IPF) 312 of FIG. 3.

In the illustrated example, one or more input devices 1122 are connected to the interface circuitry 1120. The input device(s) 1122 permit(s) a user to enter data and/or commands into the processor circuitry 1112. The input device(s) 1122 can be implemented by, for example, an audio sensor, a microphone, a camera (still or video), a keyboard, a button, a mouse, a touchscreen, a track-pad, a trackball, an isopoint device, and/or a voice recognition system.

One or more output devices 1124 are also connected to the interface circuitry 1120 of the illustrated example. The output device(s) 1124 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1120 of the illustrated example, thus, typically includes a graphics driver card, a graphics driver chip, and/or graphics processor circuitry such as a GPU.

The interface circuitry 1120 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1126. The communication can be by, for example, an Ethernet connection, a digital subscriber line (DSL) connection, a telephone line connection, a coaxial cable system, a satellite system, a line-of-site wireless system, a cellular telephone system, an optical connection, etc. In some examples, the interface circuitry 1120 is coupled to one or more of the sensors described herein in connection with the thermal degradation monitor 124 of FIG. 1. In some examples, the sensors can include the ultrasound receiver 806 of FIG. 8.

The processor platform 1100 of the illustrated example also includes one or more mass storage devices 1128 to store software and/or data. Examples of such mass storage devices 1128 include magnetic storage devices, optical storage devices, floppy disk drives, HDDs, CDs, Blu-ray disk drives, redundant array of independent disks (RAID) systems, solid state storage devices such as flash memory devices and/or SSDs, and DVD drives. The storage devices of FIG. 11 can be used to implement the example pre-shipment data repository 316, and the example actual runtime system data repository 318.

The machine readable instructions 1132, which may be implemented by the machine readable instructions of FIG. 10, may be stored in the mass storage device 1128, in the volatile memory 1114, in the non-volatile memory 1116, and/or on a removable non-transitory computer readable storage medium such as a CD or DVD.

FIG. 12 is a block diagram of an example implementation of the processor circuitry 1112 of FIG. 11. In this example, the processor circuitry 1112 of FIG. 11 is implemented by a microprocessor 1200. For example, the microprocessor 1200 may be a general purpose microprocessor (e.g., general purpose microprocessor circuitry). The microprocessor 1200 executes some or all of the machine readable instructions of the flowchart of FIG. 10 to effectively instantiate the circuitry of FIG. 2, FIG. 3 and/or FIG. 8 as logic circuits to perform the operations corresponding to those machine readable instructions. In some such examples, the circuitry of FIG. 2, FIG. 3, and FIG. 8 is instantiated by the hardware circuits of the microprocessor 1200 in combination with the instructions. For example, the microprocessor 1200 may be implemented by multi-core hardware circuitry such as a CPU, a DSP, a GPU, an XPU, etc. Although it may include any number of example cores 1202 (e.g., 1 core), the microprocessor 1200 of this example is a multi-core semiconductor device including N cores. The cores 1202 of the microprocessor 1200 may operate independently or may cooperate to execute machine readable instructions. For example, machine code corresponding to a firmware program, an embedded software program, or a software program may be executed by one of the cores 1202 or may be executed by multiple ones of the cores 1202 at the same or different times. In some examples, the machine code corresponding to the firmware program, the embedded software program, or the software program is split into threads and executed in parallel by two or more of the cores 1202. The software program may correspond to a portion or all of the machine readable instructions and/or operations represented by the flowchart of FIG. 10.

The cores 1202 may communicate by a first example bus 1204. In some examples, the first bus 1204 may be implemented by a communication bus to effectuate communication associated with one(s) of the cores 1202. For example, the first bus 1204 may be implemented by at least one of an Inter-Integrated Circuit (I2C) bus, a Serial Peripheral Interface (SPI) bus, a PCI bus, or a PCIe bus. Additionally or alternatively, the first bus 1204 may be implemented by any other type of computing or electrical bus. The cores 1202 may obtain data, instructions, and/or signals from one or more external devices by example interface circuitry 1206. The cores 1202 may output data, instructions, and/or signals to the one or more external devices by the interface circuitry 1206. Although the cores 1202 of this example include example local memory 1220 (e.g., Level 1 (L1) cache that may be split into an L1 data cache and an L1 instruction cache), the microprocessor 1200 also includes example shared memory 1210 that may be shared by the cores (e.g., Level 2 (L2 cache)) for high-speed access to data and/or instructions. Data and/or instructions may be transferred (e.g., shared) by writing to and/or reading from the shared memory 1210. The local memory 1220 of each of the cores 1202 and the shared memory 1210 may be part of a hierarchy of storage devices including multiple levels of cache memory and the main memory (e.g., the main memory 1114, 1116 of FIG. 11). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1202 may be referred to as a CPU, DSP, GPU, etc., or any other type of hardware circuitry. Each core 1202 includes control unit circuitry 1214, arithmetic and logic (AL) circuitry (sometimes referred to as an ALU) 1216, a plurality of registers 1218, the local memory 1220, and a second example bus 1222. Other structures may be present. For example, each core 1202 may include vector unit circuitry, single instruction multiple data (SIMD) unit circuitry, load/store unit (LSU) circuitry, branch/jump unit circuitry, floating-point unit (FPU) circuitry, etc. The control unit circuitry 1214 includes semiconductor-based circuits structured to control (e.g., coordinate) data movement within the corresponding core 1202. The AL circuitry 1216 includes semiconductor-based circuits structured to perform one or more mathematic and/or logic operations on the data within the corresponding core 1202. The AL circuitry 1216 of some examples performs integer based operations. In other examples, the AL circuitry 1216 also performs floating point operations. In yet other examples, the AL circuitry 1216 may include first AL circuitry that performs integer based operations and second AL circuitry that performs floating point operations. In some examples, the AL circuitry 1216 may be referred to as an Arithmetic Logic Unit (ALU). The registers 1218 are semiconductor-based structures to store data and/or instructions such as results of one or more of the operations performed by the AL circuitry 1216 of the corresponding core 1202. For example, the registers 1218 may include vector register(s), SIMD register(s), general purpose register(s), flag register(s), segment register(s), machine specific register(s), instruction pointer register(s), control register(s), debug register(s), memory management register(s), machine check register(s), etc. The registers 1218 may be arranged in a bank as shown in FIG. 12. Alternatively, the registers 1218 may be organized in any other arrangement, format, or structure including distributed throughout the core 1202 to shorten access time. The second bus 1222 may be implemented by at least one of an I2C bus, a SPI bus, a PCI bus, or a PCIe bus

Each core 1202 and/or, more generally, the microprocessor 1200 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1200 is a semiconductor device fabricated to include many transistors interconnected to implement the structures described above in one or more integrated circuits (ICs) contained in one or more packages. The processor circuitry may include and/or cooperate with one or more accelerators. In some examples, accelerators are implemented by logic circuitry to perform certain tasks more quickly and/or efficiently than can be done by a general purpose processor. Examples of accelerators include ASICs and FPGAs such as those discussed herein. A GPU or other programmable device can also be an accelerator. Accelerators may be on-board the processor circuitry, in the same chip package as the processor circuitry and/or in one or more separate packages from the processor circuitry.

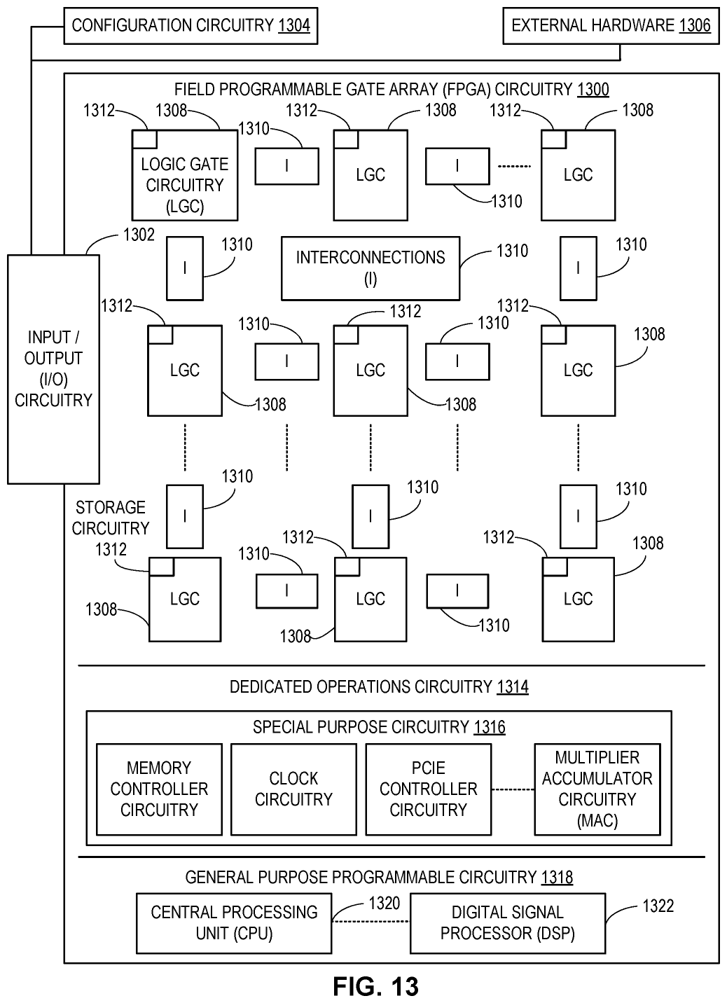

FIG. 13 is a block diagram of another example implementation of the processor circuitry 1112 of FIG. 11. In this example, the processor circuitry 1112 is implemented by FPGA circuitry 1300. For example, the FPGA circuitry 1300 may be implemented by an FPGA. The FPGA circuitry 1300 can be used, for example, to perform operations that could otherwise be performed by the example microprocessor 1200 of FIG. 12 executing corresponding machine readable instructions. However, once configured, the FPGA circuitry 1300 instantiates the machine readable instructions in hardware and, thus, can often execute the operations faster than they could be performed by a general purpose microprocessor executing the corresponding software.

More specifically, in contrast to the microprocessor 1200 of FIG. 12 described above (which is a general purpose device that may be programmed to execute some or all of the machine readable instructions represented by the flowchart of FIG. 10 but whose interconnections and logic circuitry are fixed once fabricated), the FPGA circuitry 1300 of the example of FIG. 13 includes interconnections and logic circuitry that may be configured and/or interconnected in different ways after fabrication to instantiate, for example, some or all of the machine readable instructions represented by the flowchart of FIG. 10. In particular, the FPGA circuitry 1300 may be thought of as an array of logic gates, interconnections, and switches. The switches can be programmed to change how the logic gates are interconnected by the interconnections, effectively forming one or more dedicated logic circuits (unless and until the FPGA circuitry 1300 is reprogrammed). The configured logic circuits enable the logic gates to cooperate in different ways to perform different operations on data received by input circuitry. Those operations may correspond to some or all of the software represented by the flowchart of FIG. 10. As such, the FPGA circuitry 1300 may be structured to effectively instantiate some or all of the machine readable instructions of the flowchart of FIG. 10 as dedicated logic circuits to perform the operations corresponding to those software instructions in a dedicated manner analogous to an ASIC. Therefore, the FPGA circuitry 1300 may perform the operations corresponding to the some or all of the machine readable instructions of FIG. 10 faster than the general purpose microprocessor can execute the same.

In the example of FIG. 13, the FPGA circuitry 1300 is structured to be programmed (and/or reprogrammed one or more times) by an end user by a hardware description language (HDL) such as Verilog. The FPGA circuitry 1300 of FIG. 13, includes example input/output (I/O) circuitry 1302 to obtain and/or output data to/from example configuration circuitry 1304 and/or external hardware 1306. For example, the configuration circuitry 1304 may be implemented by interface circuitry that may obtain machine readable instructions to configure the FPGA circuitry 1300, or portion(s) thereof. In some such examples, the configuration circuitry 1304 may obtain the machine readable instructions from a user, a machine (e.g., hardware circuitry (e.g., programmed or dedicated circuitry) that may implement an Artificial Intelligence/Machine Learning (AI/ML) model to generate the instructions), etc. In some examples, the external hardware 1306 may be implemented by external hardware circuitry. For example, the external hardware 1306 may be implemented by the microprocessor 1200 of FIG. 12. The FPGA circuitry 1300 also includes an array of example logic gate circuitry 1308, a plurality of example configurable interconnections 1310, and example storage circuitry 1312. The logic gate circuitry 1308 and the configurable interconnections 1310 are configurable to instantiate one or more operations that may correspond to at least some of the machine readable instructions of FIG. 10 and/or other desired operations. The logic gate circuitry 1308 shown in FIG. 13 is fabricated in groups or blocks. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1308 to enable configuration of the electrical structures and/or the logic gates to form circuits to perform desired operations. The logic gate circuitry 1308 may include other electrical structures such as look-up tables (LUTs), registers (e.g., flip-flops or latches), multiplexers, etc.

The configurable interconnections 1310 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1308 to program desired logic circuits.

The storage circuitry 1312 of the illustrated example is structured to store result(s) of the one or more of the operations performed by corresponding logic gates. The storage circuitry 1312 may be implemented by registers or the like. In the illustrated example, the storage circuitry 1312 is distributed amongst the logic gate circuitry 1308 to facilitate access and increase execution speed.

The example FPGA circuitry 1300 of FIG. 13 also includes example Dedicated Operations Circuitry 1314. In this example, the Dedicated Operations Circuitry 1314 includes special purpose circuitry 1316 that may be invoked to implement commonly used functions to avoid the need to program those functions in the field. Examples of such special purpose circuitry 1316 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1300 may also include example general purpose programmable circuitry 1318 such as an example CPU 1320 and/or an example DSP 1322. Other general purpose programmable circuitry 1318 may additionally or alternatively be present such as a GPU, an XPU, etc., that can be programmed to perform other operations.

Although FIGS. 12 and 13 illustrate two example implementations of the processor circuitry 1112 of FIG. 11, many other approaches are contemplated. For example, as mentioned above, modern FPGA circuitry may include an on-board CPU, such as one or more of the example CPU 1320 of FIG. 13. Therefore, the processor circuitry 1112 of FIG. 11 may additionally be implemented by combining the example microprocessor 1200 of FIG. 12 and the example FPGA circuitry 1300 of FIG. 13. In some such hybrid examples, a first portion of the machine readable instructions represented by the flowchart of FIG. 10 may be executed by one or more of the cores 1202 of FIG. 12, a second portion of the machine readable instructions represented by the flowchart of FIG. 10 may be executed by the FPGA circuitry 1300 of FIG. 13, and/or a third portion of the machine readable instructions represented by the flowchart of FIG. 10 may be executed by an ASIC. It should be understood that some or all of the circuitry of FIG. 2, FIG. 3 and/or FIG. 8 may, thus, be instantiated at the same or different times. Some or all of the circuitry may be instantiated, for example, in one or more threads executing concurrently and/or in series. Moreover, in some examples, some or all of the circuitry of FIG. 2, FIG. 3 and/or FIG. 8 may be implemented within one or more virtual machines and/or containers executing on the microprocessor.

In some examples, the processor circuitry 1112 of FIG. 11 may be in one or more packages. For example, the microprocessor 1200 of FIG. 12 and/or the FPGA circuitry 1300 of FIG. 13 may be in one or more packages. In some examples, an XPU may be implemented by the processor circuitry 1112 of FIG. 11, which may be in one or more packages. For example, the XPU may include a CPU in one package, a DSP in another package, a GPU in yet another package, and an FPGA in still yet another package.

From the foregoing, it will be appreciated that example systems, methods, apparatus, and articles of manufacture have been disclosed that monitor thermal degradation and trigger alerts and/or operations to be taken to improve the ability of the compute device to successfully dissipate heat. Disclosed systems, methods, apparatus, and articles of manufacture improve the efficiency of using a compute device by reducing the damage that occurs to compute devices due to thermal degradation, by alerting a user when a thermal interface material of the compute device is degrading, alerting a user when a compute device fan inlet/outlet is blocked by dust, improving the ability of the compute device to operate at a desired power level without experiencing slow down due to thermal degradation, etc. Disclosed systems, methods, apparatus, and articles of manufacture are accordingly directed to one or more improvement(s) in the operation of a machine such as a computer or other electronic and/or mechanical device.

Example methods, apparatus, systems, and articles of manufacture to monitor thermal degradation of a compute device are disclosed herein. Further examples and combinations thereof include the following:

Example 1 includes an apparatus to monitor thermal degradation of a compute device comprising interface circuitry to interface with one or more sensors that monitor one or more characteristics of the compute device, and processor circuitry including one or more of at least one of a central processor unit, a graphics processor unit, or a digital signal processor, the at least one of the central processor unit, the graphics processor unit, or the digital signal processor having control circuitry to control data movement within the processor circuitry, arithmetic and logic circuitry to perform one or more first operations corresponding to instructions, and one or more registers to store a result of the one or more first operations, the instructions in the apparatus, a Field Programmable Gate Array (FPGA), the FPGA including logic gate circuitry, a plurality of configurable interconnections, and storage circuitry, the logic gate circuitry and the plurality of the configurable interconnections to perform one or more second operations, the storage circuitry to store a result of the one or more second operations, or Application Specific Integrated Circuitry (ASIC) including logic gate circuitry to perform one or more third operations, the processor circuitry to perform at least one of the first operations, the second operations, or the third operations to instantiate calculator circuitry to calculate a thermal interface material degradation index (TGI) value based on sensor information values from the interface circuitry, comparator circuitry to compare the TGI value to a TGI threshold to determine whether the TGI value satisfies the TGI threshold, and alert trigger circuitry to trigger generation of a thermal degradation alert when the TGI threshold is satisfied.

Example 2 includes the apparatus of example 1, wherein the calculator circuitry is first calculator circuitry, the comparator circuitry is first comparator circuitry, and the alert trigger circuitry is first alert trigger circuitry, and the processor circuitry is to instantiate second calculator circuitry to calculate a fan inlet/outlet blockage index (FIBI) value based on sensor information from the interface circuitry, the sensor information to include one or more fan speed values, second comparator circuitry to compare the FIBI value to a FIBI threshold to determine whether the FIBI value satisfies the FIBI threshold, and second alert trigger circuitry to trigger generation of the thermal degradation alert when the FIBI threshold is satisfied, the thermal degradation alert to at least one of i) indicate that a fan inlet/outlet vent associated with the processor circuitry is blocked, ii) indicate that the compute device is operating at a temperature that can cause thermal degradation, or iii) trigger a self-cleaning operation to be performed.

Example 3 includes the apparatus of example 1, wherein the one or more sensors include an ultrasound receiver and a timer to determine an amount of time an ultrasound signal generated by an ultrasound transmitter takes to travel through a thermal interface material (TIM) of the compute device to the ultrasound receiver.

Example 4 includes the apparatus of example 3, wherein the processor circuitry is to instantiate monitor circuitry to determine whether the amount of time satisfies a TIM degradation threshold.

Example 5 includes the apparatus of example 1, wherein the processor circuitry is to instantiate validation circuitry to validate the thermal degradation alert.

Example 6 includes the apparatus of example 5, wherein the validation circuitry is to cause an ultrasound signal to be transmitted through a TIM of the compute device, determine an amount of time the ultrasound signal traverses a length of the TIM, determine a state of degradation of the TIM based on the amount of time, and validate the thermal degradation alert based on the state of degradation of the TIM.

Example 7 includes the apparatus of example 5, wherein the validation circuitry is to determine whether the TIM is degraded based on a standard thermal degradation model and an amount of capacitance associated with the thermal interface material operating value.

Example 8 includes an apparatus comprising at least one memory, machine readable instructions, and processor circuitry to at least one of instantiate or execute the machine readable instructions to calculate a first value to represent an amount of thermal interface material degradation, the first value based on an equation, the equation generated based on test data collected from compute devices having respective thermal interface materials, the respective thermal interface materials of the compute devices in varying levels of degradation, compare the first value to a first threshold to determine whether the first threshold is satisfied, and generate a first alert when the first threshold is satisfied.

Example 9 includes the apparatus of example 8, wherein the processor circuitry is to calculate a second value to represent an amount of blockage of a fan vent, the second value based on one or more fan sensor output values, compare the second value to a second threshold to determine whether the second threshold is satisfied, and generate a second when the second threshold is satisfied, the second alert to at least one of i) indicate that the fan vent is at least partially blocked, ii) trigger a self-cleaning operation to be performed, or iii) trigger generation of the first alert.

Example 10 includes the apparatus of example 8, wherein the processor circuitry is to, prior to generation of the first alert, verify the first alert based on i) whether a thermal interface material (TIM) associated with the apparatus is degraded, the thermal interface material degraded when at least one of i) an amount of time an ultrasound signal travels through the TIM exceeds a second threshold, or ii) evaluation of degradation model based on a capacitive value of the TIM indicates the TIM is degraded, when the first alert is validated, determine whether the apparatus includes a fan, when the apparatus is fanless, cause the processor circuitry to trigger the generation of the first alert.

Example 11 includes the apparatus of example 10, wherein, when the apparatus includes the fan, the processor circuitry is to determine whether at least a first amount of area of a fan vent associated with the fan is blocked, the first amount of area associated with thermal degradation, and when less than the at least the first amount of area of the fan vent is blocked, cause the processor circuitry to delay generation of the first alert until the at least the first amount of area of the fan vent is blocked.

Example 12 includes the apparatus of example 8, wherein the apparatus includes a monitor, the monitor to include an ultrasound transmitter, an ultrasound receiver, and a timer to determine a travel time of an ultrasound signal generated by the ultrasound transmitter through a TIM to the ultrasound receiver, the TIM associated with the apparatus.

Example 13 includes a non-transitory machine readable storage medium comprising instructions that, when executed, cause processor circuitry to at least calculate a thermal degradation value based on an equation and runtime data collected from a compute device, the equation generated based on testing of thermal interface materials (TIMs) at varying levels of degradation, calculate a thermal degradation threshold based on one or more thermal degradation curves, the one or more thermal degradation curves based on the equation and test data generated when testing the TIMs, compare the thermal degradation value to the thermal degradation threshold to determine whether the thermal degradation value satisfies the thermal degradation threshold, and when the thermal degradation value satisfies the thermal degradation threshold, trigger generation of a thermal degradation alert.

Example 14 includes the non-transitory machine readable storage medium of example 13, wherein the equation is a first equation, and the instructions, when executed, cause the processor circuitry calculate a fan inlet/outlet blockage value based on a second equation, the second equation based on testing of fan inlet/outlets having varying levels of blockage, compare the fan inlet/outlet blockage value to a fan inlet/outlet blockage threshold to determine whether the fan inlet/outlet blockage value satisfies the fan inlet/outlet blockage threshold, and trigger generation of an alert when the fan inlet/outlet blockage threshold is satisfied, the alert to at least one of i) indicate that blockage of a fan inlet/outlet associated with the compute device is negatively impacting operation of the compute device, ii) trigger a self-cleaning operation to be performed on the fan inlet/outlet, or iii) indicate the compute device is operating at a temperature that can cause damage to the compute device.

Example 15 includes the non-transitory machine readable storage medium of example 14, wherein the triggering generation of the thermal degradation alert is to be delayed, and the instructions, when executed, cause the processor circuitry determine a TIM degradation value based on runtime data generated by the compute device and a TIM degradation model accessible to the apparatus, and compare the TIM degradation value to a TIM degradation threshold to determine whether the TIM degradation value satisfies the TIM degradation threshold, when the TIM degradation value satisfies the TIM degradation threshold, validate that the thermal degradation alert is warranted, and prevent further delay of triggering generation of the thermal degradation alert.

Example 16 includes the non-transitory machine readable storage medium of example 13, wherein, prior to triggering generation of the thermal degradation alert, the instructions, when executed, cause the processor circuitry determine a travel time of an ultrasound signal through the TIM of the compute device, and when the travel time exceeds a threshold travel time, validate that the thermal degradation alert is warranted, do not delay triggering generation of the thermal degradation, when the travel time does not exceed the threshold travel time, do not validate that the thermal degradation alert is warranted, and delay triggering generation of the thermal degradation.

Example 17 includes a method comprising calculating, by executing instructions with processor circuitry, a thermal degradation value based on an equation, the equation generated based on testing of thermal interface materials having varying degrees of degradation, comparing, by executing instructions with the processor circuitry, the thermal degradation value to a thermal degradation threshold to determine whether the TGI threshold is satisfied, and when the thermal degradation threshold is satisfied, triggering generation of a thermal degradation alert.

Example 18 includes the method of example 17, including calculating a fan inlet/outlet blockage index (FIBI) value based on an equation, the equation generated based on testing data collected from one or more fan inlet/outlets having varying degrees of blockage, comparing the FIBI value to a FIBI threshold to determine whether the FIBI threshold is satisfied, the FIBI threshold based on one or more curves, the one or more curves generated based on the testing data, and generating an alert when the FIBI threshold is satisfied, the alert to indicate that a fan inlet/outlet vent associated with the processor circuitry is blocked, and triggering generation of the thermal degradation alert and triggering a fan self-cleaning operation.

Example 19 includes the method of example 17, including determining a duration of time an ultrasound signal generated by an ultrasound transmitter takes to travel through the length of a thermal interface material (TIM) of a compute device, and when the duration of time satisfies a threshold duration of time, validating the thermal degradation alert signal as being warranted.

Example 20 includes the method of example 19, including delaying triggering generation of the thermal degradation alert until the thermal degradation alert signal is validated as being warranted.

The following claims are hereby incorporated into this Detailed Description by this reference. Although certain example systems, methods, apparatus, and articles of manufacture have been disclosed herein, the scope of coverage of this patent is not limited thereto. On the contrary, this patent covers all systems, methods, apparatus, and articles of manufacture fairly falling within the scope of the claims of this patent.

what is claimed is:

1. An apparatus to monitor thermal degradation of a compute device comprising:
interface circuitry to interface with one or more sensors that monitor one or more characteristics of the compute device; and
processor circuitry including one or more of:
at least one of a central processor unit, a graphics processor unit, or a digital signal processor, the at least one of the central processor unit, the graphics processor unit, or the digital signal processor having control circuitry to control data movement within the processor circuitry, arithmetic and logic circuitry to perform one or more first operations corresponding to instructions, and one or more registers to store a result of the one or more first operations, the instructions in the apparatus;
a Field Programmable Gate Array (FPGA), the FPGA including logic gate circuitry, a plurality of configurable interconnections, and storage circuitry, the logic gate circuitry and the plurality of the configurable interconnections to perform one or more second operations, the storage circuitry to store a result of the one or more second operations; or
Application Specific Integrated Circuitry (ASIC) including logic gate circuitry to perform one or more third operations;
the processor circuitry to perform at least one of the first operations, the second operations, or the third operations to instantiate:
calculator circuitry to calculate a thermal interface material degradation index (TGI) value based on sensor information from the interface circuitry;
comparator circuitry to compare the TGI value to a TGI threshold to determine whether the TGI value satisfies the TGI threshold; and
alert trigger circuitry to trigger generation of a thermal degradation alert when the TGI threshold is satisfied.

2. The apparatus of claim 1, wherein the calculator circuitry is first calculator circuitry, the comparator circuitry is first comparator circuitry, and the alert trigger circuitry is first alert trigger circuitry, and the processor circuitry is to instantiate:
second calculator circuitry to calculate a fan inlet/outlet blockage index (FIBI) value based on sensor information from the interface circuitry, the sensor information to include one or more fan speed values;
second comparator circuitry to compare the FIBI value to a FIBI threshold to determine whether the FIBI value satisfies the FIBI threshold; and
second alert trigger circuitry to trigger generation of the thermal degradation alert when the FIBI threshold is satisfied, the thermal degradation alert to at least one of i) indicate that a fan inlet/outlet vent associated with the processor circuitry is blocked, ii) indicate that the compute device is operating at a temperature that can cause thermal degradation, or iii) trigger a self-cleaning operation to be performed.

3. The apparatus of claim 1, wherein the one or more sensors include an ultrasound receiver and a timer to determine an amount of time an ultrasound signal generated by an ultrasound transmitter takes to travel through a thermal interface material (TIM) of the compute device to the ultrasound receiver.

4. The apparatus of claim 3, wherein the processor circuitry is to instantiate monitor circuitry to determine whether the amount of time satisfies a TIM degradation threshold.

5. The apparatus of claim 1, wherein the processor circuitry is to instantiate validation circuitry to validate the thermal degradation alert.

6. The apparatus of claim 5, wherein the validation circuitry is to:
cause an ultrasound signal to be transmitted through a thermal interface material (TIM) of the compute device;
determine an amount of time the ultrasound signal traverses a length of the TIM;
determine a state of degradation of the TIM based on the amount of time; and
validate the thermal degradation alert based on the state of degradation of the TIM.

7. The apparatus of claim 5, wherein the validation circuitry is to determine whether a thermal interface material (TIM) is degraded based on a standard thermal degradation model, the standard thermal degradation model defining a relationship between a length of operating time of the TIM and a capacitance of the TIM.

8. An apparatus comprising:
at least one memory;
machine readable instructions; and
processor circuitry to at least one of instantiate or execute the machine readable instructions to:
calculate a first value to represent an amount of thermal interface material degradation, the first value based on an equation, the equation generated based on test data collected from compute devices having respective thermal interface materials, the respective thermal interface materials of the compute devices in varying levels of degradation;
compare the first value to a first threshold to determine whether the first threshold is satisfied; and
generate a first alert when the first threshold is satisfied.

9. The apparatus of claim 8, wherein the processor circuitry is to:
calculate a second value to represent an amount of blockage of a fan vent, the second value based on one or more fan sensor output values;
compare the second value to a second threshold to determine whether the second threshold is satisfied; and
generate a second when the second threshold is satisfied, the second alert to at least one of i) indicate that the fan vent is at least partially blocked, ii) trigger a self-cleaning operation to be performed, or iii) trigger generation of the first alert.

10. The apparatus of claim 8, wherein the processor circuitry is to, prior to generation of the first alert,
verify the first alert based on i) whether a thermal interface material (TIM) associated with the apparatus is degraded, the thermal interface material degraded when at least one of i) an amount of time an ultrasound signal travels through the TIM exceeds a second threshold, or ii) evaluation of degradation model based on a capacitive value of the TIM indicates the TIM is degraded;
when the first alert is validated, determine whether the apparatus includes a fan; and
when the apparatus is fanless, cause the processor circuitry to trigger the generation of the first alert.

11. The apparatus of claim 10, wherein, when the apparatus includes the fan, the processor circuitry is to:
determine whether at least a first amount of area of a fan vent associated with the fan is blocked, the first amount of area associated with thermal degradation; and
when less than the at least the first amount of area of the fan vent is blocked, cause the processor circuitry to delay generation of the first alert until the at least the first amount of area of the fan vent is blocked.

12. The apparatus of claim 8, wherein the apparatus includes a monitor, the monitor to include:
an ultrasound transmitter;
an ultrasound receiver; and
a timer to determine a travel time of an ultrasound signal generated by the ultrasound transmitter through a TIM to the ultrasound receiver, the TIM associated with the apparatus.

13. A non-transitory machine readable storage medium comprising instructions that, when executed, cause processor circuitry to at least:
calculate a thermal degradation value based on an equation and runtime data collected from a compute device, the equation generated based on testing of thermal interface materials (TIMs) at varying levels of degradation;
calculate a thermal degradation threshold based on one or more thermal degradation curves, the one or more thermal degradation curves based on the equation and test data generated when testing the TIMs;
compare the thermal degradation value to the thermal degradation threshold to determine whether the thermal degradation value satisfies the thermal degradation threshold; and
when the thermal degradation value satisfies the thermal degradation threshold, trigger generation of a thermal degradation alert.

14. The non-transitory machine readable storage medium of claim 13, wherein the equation is a first equation, and the instructions, when executed, cause the processor circuitry:
calculate a fan inlet/outlet blockage value based on a second equation, the second equation based on testing of fan inlet/outlets having varying levels of blockage;
compare the fan inlet/outlet blockage value to a fan inlet/outlet blockage threshold to determine whether the fan inlet/outlet blockage value satisfies the fan inlet/outlet blockage threshold; and
trigger generation of an alert when the fan inlet/outlet blockage threshold is satisfied, the alert to at least one of i) indicate that blockage of a fan inlet/outlet associated with the compute device is negatively impacting operation of the compute device, ii) trigger a self-cleaning operation to be performed on the fan inlet/outlet, or iii) indicate the compute device is operating at a temperature that can cause damage to the compute device.

15. The non-transitory machine readable storage medium of claim 14, wherein the triggering generation of the thermal degradation alert is to be delayed, and the instructions, when executed, cause the processor circuitry:
determine a TIM degradation value based on runtime data generated by the compute device and a TIM degradation model; and
compare the TIM degradation value to a TIM degradation threshold to determine whether the TIM degradation value satisfies the TIM degradation threshold;
when the TIM degradation value satisfies the TIM degradation threshold, validate that the thermal degradation alert is warranted; and
prevent further delay of triggering generation of the thermal degradation alert.

16. The non-transitory machine readable storage medium of claim 13, wherein, prior to triggering generation of the thermal degradation alert, the instructions, when executed, cause the processor circuitry determine a travel time of an ultrasound signal through the TIM of the compute device; and
when the travel time exceeds a threshold travel time, validate that the thermal degradation alert is warranted;
do not delay triggering generation of the thermal degradation;
when the travel time does not exceed the threshold travel time, do not validate that the thermal degradation alert is warranted; and
delay triggering generation of the thermal degradation.

17. A method comprising:
calculating, by executing instructions with processor circuitry, a thermal degradation value based on an equation, the equation generated based on testing of thermal interface materials having varying degrees of degradation;
comparing, by executing instructions with the processor circuitry, the thermal degradation value to a thermal degradation threshold to determine whether a thermal degradation threshold is satisfied; and
when the thermal degradation threshold is satisfied, triggering generation of a thermal degradation alert.

18. The method of claim 17, including:
calculating a fan inlet/outlet blockage index (FIBI) value based on an equation, the equation generated based on testing data collected from one or more fan inlet/outlets having varying degrees of blockage;
comparing the FIBI value to a FIBI threshold to determine whether the FIBI threshold is satisfied, the FIBI threshold based on one or more curves, the one or more curves generated based on the testing data; and
generating an alert when the FIBI threshold is satisfied, the alert to indicate that a fan inlet/outlet vent associated with the processor circuitry is blocked; and
triggering generation of the thermal degradation alert and triggering a fan self-cleaning operation.

19. The method of claim 17, including:
determining a duration of time an ultrasound signal generated by an ultrasound transmitter takes to travel through a length of a thermal interface material (TIM) of a compute device; and
when the duration of time satisfies a threshold duration of time, validating the thermal degradation alert as being warranted.

20. The method of claim 19, including delaying triggering generation of the thermal degradation alert until the thermal degradation alert signal is validated as being warranted.
